(19) United States
(12) Patent Application Publication
(10) Pub. No.: US 2026/0025979 A1
(43) Pub. Date: Jan. 22, 2026

(54) SEMICONDUCTOR MEMORY DEVICE

(71) Applicant: Samsung Electronics Co., Ltd., Suwon-si (KR)

(72) Inventor: Min Hee Cho, Suwon-si (KR)

(21) Appl. No.: 19/188,229

(22) Filed: Apr. 24, 2025

(30) Foreign Application Priority Data
Jul. 18, 2024 (KR) 10-2024-0094998

(51) Int. Cl. H10B 12/00

(52) U.S. Cl. CPC H10B 12/33; H10B 12/05; H10B 12/50

(57) ABSTRACT

A semiconductor memory device may include a contact pattern including a first surface and a second surface opposite to each other in a first direction, a data storage pattern electrically connected to the first surface of the contact pattern, a channel pattern including a first surface and a second surface opposite to each other in the first direction, and a first sidewall and a second sidewall opposite to each other in a second direction, wherein the first surface of the channel pattern is electrically connected to the contact pattern, and at least a portion of the first sidewall of the channel pattern is in contact with the contact pattern, a bitline on the channel pattern, electrically connected to the second surface of the channel pattern, and extending in the second direction, and a wordline on the second sidewall of the channel pattern and extending in a third direction.

### CROSS-REFERENCE TO RELATED APPLICATIONS

This application claims priority to Korean Patent Application No. 10-2024-0094998 filed on Jul. 18, 2024 in the Korean Intellectual Property Office, and all the benefits accruing therefrom under 35 U.S.C. 119, the contents of which in its entirety are herein incorporated by reference.

### BACKGROUND OF THE INVENTION

The present disclosure relates to a semiconductor memory device and, more particularly, to a semiconductor memory device including vertical channel transistors (VCTs).

To meet consumer demands for excellent performance and low cost, increasing the integration density of semiconductor memory devices is helpful. Since the integration density of semiconductor memory devices is a crucial factor in determining the product price, higher integration density is beneficial.

The integration density of two-dimensional (2D) or planar semiconductor memory devices is primarily determined by the area occupied by unit memory cells and is thus greatly influenced by the level of fine patterning technology. However, since ultra-high-cost equipment is needed for miniaturizing patterns, the integration density of 2D semiconductor memory devices, although increasing, remains limited. Accordingly, semiconductor memory devices including vertical channel transistors (VCTs), where the channels extend vertically, have been proposed.

### SUMMARY OF THE INVENTION

Aspects of the present disclosure provide a semiconductor memory device with improved integration density and electrical characteristics.

However, aspects of the present disclosure are not limited to those set forth herein. The above and other aspects of the present disclosure will become more apparent to one of ordinary skill in the art to which the present disclosure pertains by referencing the detailed description of the present disclosure given below.

According to some aspects of the present disclosure, there is provided a semiconductor memory device comprising a contact pattern including a first surface and a second surface that are opposite to each other in a first direction, a data storage pattern electrically connected to the first surface of the contact pattern, a channel pattern including a first surface and a second surface that are opposite to each other in the first direction, and a first sidewall and a second sidewall that are opposite to each other in a second direction different from the first direction, wherein the first surface of the channel pattern is electrically connected to the contact pattern, and at least a portion of the first sidewall of the channel pattern is in contact with the contact pattern, a bitline on the channel pattern, electrically connected to the second surface of the channel pattern, and extending in the second direction, and a wordline on the second sidewall of the channel pattern and extending in a third direction different from the first and second directions.

According to some aspects of the present disclosure, there is provided a semiconductor memory device comprising a contact pattern including a first surface and a second surface that are opposite to each other in a first direction, a data storage pattern electrically connected to the first surface of the contact pattern, a channel pattern including a first surface and a second surface that are opposite to each other in the first direction, wherein the first surface of the channel pattern is electrically connected to the contact pattern, a bitline on the channel pattern, electrically connected to the second surface of the channel pattern, and extending in a second direction different from the first direction, a wordline between the bitline and the contact pattern, and extending in a third direction different from the first and second directions, and a gate insulating film between the wordline and the channel pattern, wherein the contact pattern comprises a lower portion that includes the first surface of the contact pattern and an upper portion that includes the second surface of the contact pattern, wherein the upper portion of the contact pattern protrudes in the first direction from the lower portion of the contact pattern, wherein a width, in the second direction, of the upper portion of the contact pattern is less than a width, in the second direction, of the lower portion of the contact pattern, and wherein the first surface of the channel pattern is in contact with the lower portion of the contact pattern.

According to some aspects of the present disclosure, there is provided a semiconductor memory device comprising a peripheral gate structure on a substrate, a contact pattern on the peripheral gate structure, the contact pattern including a first surface and a second surface that are opposite to each other in a first direction, a data storage pattern electrically connected to the first surface of the contact pattern, a channel pattern including a first surface and a second surface that are opposite to each other in the first direction, wherein the first surface of the channel pattern is in contact with the contact pattern, a bitline on the channel pattern, electrically connected to the second surface of the channel pattern, and extending in a second direction different from the first direction, and a wordline between the bitline and the contact pattern, and extending in a third direction different from the first and second directions, wherein, in a cross- sectional view, a length of an interface where the channel pattern is in contact with the contact pattern is greater than a width, in the second direction, of the first surface of the channel pattern.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic layout view of a semiconductor memory device according to some embodiments.

FIG. 2 is a layout view of a cell array area of FIG. 1.

FIG. 3 is a cross-sectional view taken along lines A-A and B-B of FIG. 2.

FIG. 4 is a cross-sectional view taken along lines C-C and D-D of FIG. 2.

FIG. 5 is an enlarged cross-sectional view of part P of FIG. 3.

FIG. 6 is a cross-sectional view that illustrates the shape of a contact pattern in FIG. 5.

FIGS. 7 and 8 are cross-sectional views that illustrate semiconductor memory devices according to some embodiments.

FIGS. 9 through 12 are cross-sectional views that illustrate semiconductor memory devices according to some embodiments.

FIGS. 13 through 15 are cross-sectional views that illustrate semiconductor memory devices according to some embodiments.

FIG. 16 is a cross-sectional view that illustrates a semiconductor memory device according to some embodiments.

FIG. 17 is a cross-sectional view that illustrates a semiconductor memory device according to some embodiments.

FIG. 18 is a cross-sectional view that illustrates a semiconductor memory device according to some embodiments.

FIG. 19 is a cross-sectional view that illustrates a semiconductor memory device according to some embodiments.

FIG. 20 is a cross-sectional view that illustrates a semiconductor memory device according to some embodiments.

FIGS. 21 and 22 are cross-sectional views that illustrate a semiconductor memory device according to some embodiments.

FIGS. 23 and 24 are cross-sectional views that illustrate a semiconductor memory device according to some embodiments.

FIGS. 25 through 28 are layout views that illustrate semiconductor memory devices according to some embodiments.

FIGS. 29 through 37 are views that illustrate a method of manufacturing a semiconductor memory device according to some embodiments.

### DETAILED DESCRIPTION

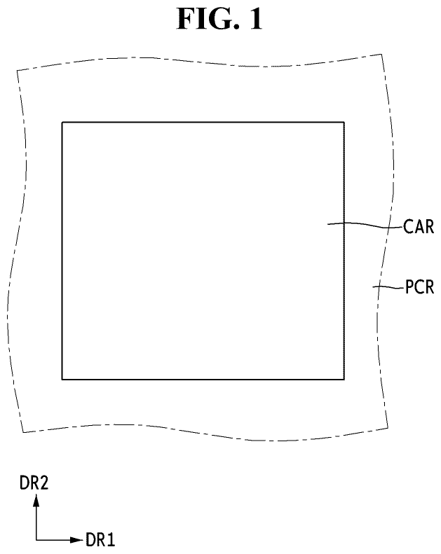

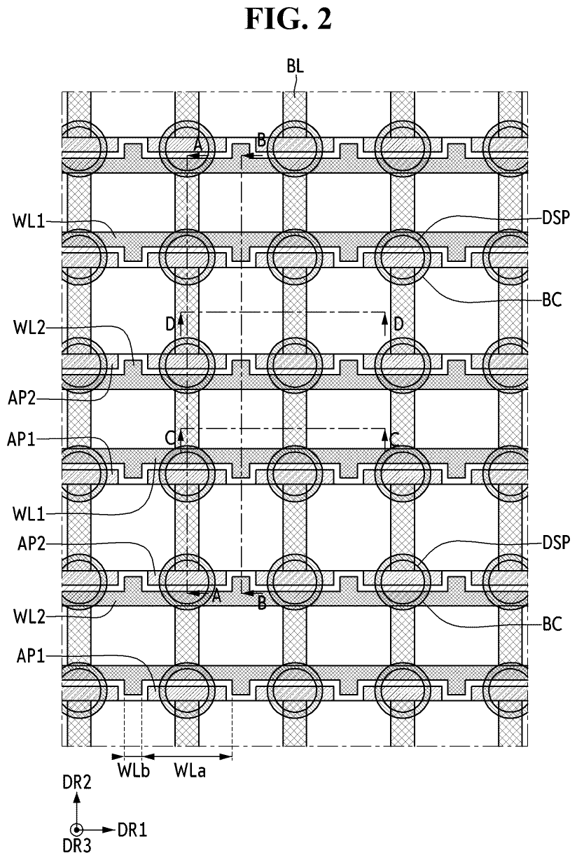

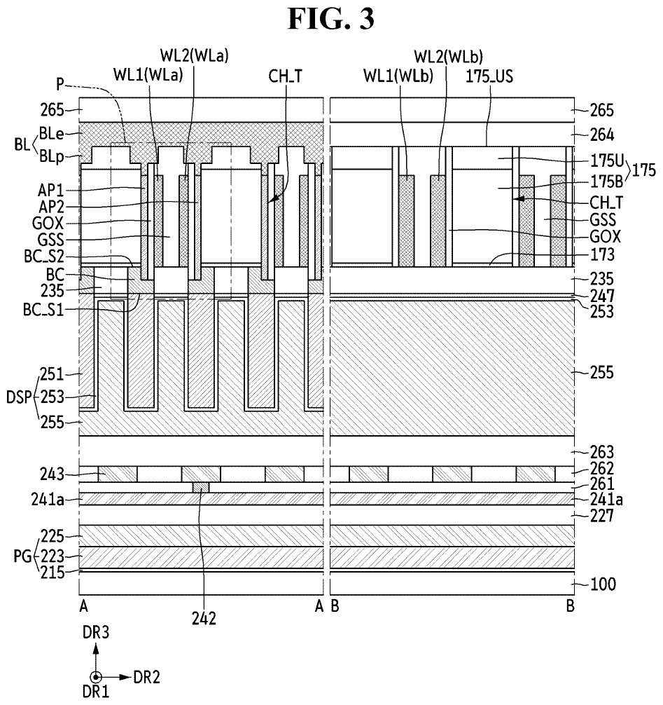

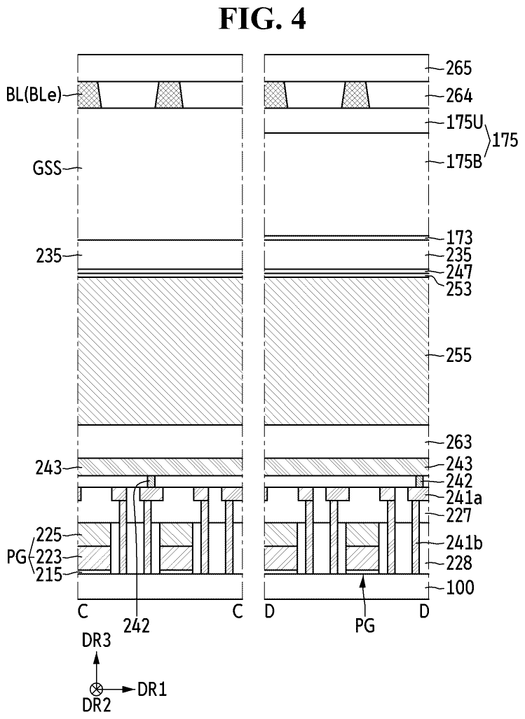

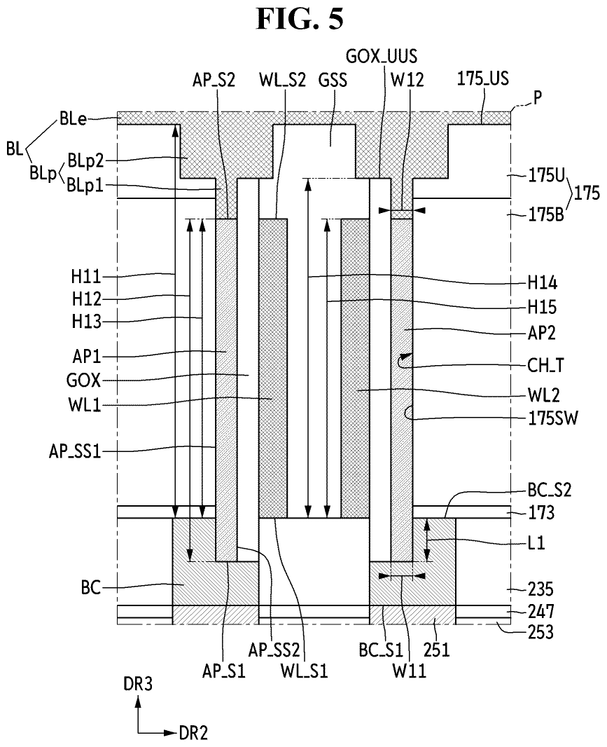

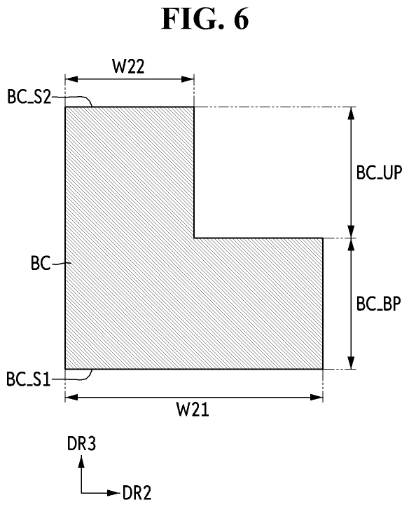

FIG. 1 is a schematic layout view of a semiconductor memory device according to some embodiments. FIG. 2 is a layout view of a cell array area of FIG. 1. FIG. 3 is a cross-sectional view taken along lines A-A and B-B of FIG. 2. FIG. 4 is a cross-sectional view taken along lines C-C and D-D of FIG. 2. FIG. 5 is an enlarged cross-sectional view of part P of FIG. 3. FIG. 6 is a cross-sectional view that illustrates the shape of a contact pattern in FIG. 5.

The semiconductor memory device according to some embodiments may include memory cells that include vertical channel transistors (VCTs).

Referring to FIGS. 1 through 6, the semiconductor memory device according to some embodiments may include a peripheral gate structure PG, bitlines BL, wordlines WL1 and WL2, channel patterns AP1 and AP2, contact patterns BC, and data storage patterns DSP.

A substrate 100 may include a cell array area CAR where the data storage patterns DSP are disposed, and a peripheral circuit area PCR defined around the cell array area CAR. The substrate 100 may be a silicon substrate, or may include other materials, for example, silicon- germanium, indium antimonide, a lead telluride compound, indium arsenide, indium phosphide, gallium arsenide, or gallium antimonide, but the present disclosure is not limited thereto.

The peripheral gate structure PG may be disposed on the substrate 100. The substrate 100 may include the cell array area CAR and the peripheral circuit area PCR. The peripheral gate structure PG may be arranged over both the cell array area CAR and the peripheral circuit area PCR. In other words, part of the peripheral gate structure PG may be disposed in the cell array area CAR of the substrate 100, and the rest of the peripheral gate structure PG may be disposed in the peripheral circuit area PCR of the substrate 100.

The peripheral gate structure PG may include sensing transistors, transfer transistors, and driving transistors. The types of transistors disposed in the cell array area CAR and the peripheral circuit area PCR may vary depending on the design layout of the semiconductor memory device according to some embodiments.

The peripheral gate structure PG may include a peripheral gate insulating film 215, peripheral lower conductive patterns 223, and peripheral upper conductive patterns 225. The peripheral gate insulating film 215 may include a silicon oxide film, a silicon oxynitride film, a high-k dielectric film with a higher dielectric constant than a silicon oxide film, or a combination thereof. The high-k dielectric film may include, for example, at least one of a metal oxide, a metal oxynitride, a metal silicon oxide, or a metal silicon oxynitride, but the present disclosure is not limited thereto.

The peripheral lower conductive patterns 223 and the peripheral upper conductive patterns 225 may each include a conductive material. For example, the peripheral lower conductive patterns 223 and the peripheral upper conductive patterns 225 may each include at least one of a doped semiconductor material, conductive metal nitride, conductive metal silicon nitride, metal carbonitride, conductive metal silicide, conductive metal oxide, a two-dimensional (2D) material, a metal, or a metal alloy. The peripheral gate structure PG is illustrated as including multiple conductive patterns, but the present disclosure is not limited thereto.

In the semiconductor memory device according to some embodiments, the 2D material may be a metallic and/or semiconductor material. The 2D material may include a 2D allotrope or 2D compound, for example, at least one of graphene, molybdenum disulfide (MoS₂), molybdenum diselenide (MoSe₂), tungsten diselenide (WSe₂), or tungsten disulfide (WS₂), but the present disclosure is not limited thereto. That is, these 2D materials are merely illustrative, and the present disclosure is not limited thereto.

A first peripheral lower insulating film 227 and a second peripheral lower insulating film 228 are disposed on the substrate 100. The first peripheral lower insulating film 227 and the second peripheral lower insulating film 228 may each be formed of an insulating material.

The second peripheral lower insulating film 228 is illustrated as being in contact with the sidewalls of the peripheral lower conductive patterns 223 and the sidewalls of the peripheral upper conductive patterns 225, but the present disclosure is not limited thereto. In some embodiments, the peripheral gate structure PG may include peripheral gate spacers disposed on the sidewalls of the peripheral lower conductive patterns 223 and the sidewalls of the peripheral upper conductive patterns 225.

Peripheral wiring lines 241a and the peripheral contact plug 241b may be disposed within the first peripheral lower insulating film 227 and the second peripheral lower insulating film 228, respectively. Peripheral contact plugs 241b may be connected to a source/drain region disposed on at least one side of the peripheral gate structure PG. For example, the source/drain region may be a region doped with impurities in the substrate 100, but the present disclosure is not limited thereto. Although not illustrated, the peripheral contact plugs 241b may be connected to the peripheral conductive patterns 223 and 225 of the peripheral gate structure PG.

The peripheral wiring lines 241a may be disposed on the peripheral contact plugs 241b. The peripheral wiring lines 241a are connected to the peripheral contact plugs 241b. For example, the peripheral wiring lines 241a may be wiring lines closest to the peripheral gate structure PG in a third direction DR3.

The peripheral wiring lines 241a and the peripheral contact plugs 241b are illustrated as being different films, but the present disclosure is not limited thereto. In some embodiments, the boundaries between the peripheral wiring lines 241a and the peripheral contact plugs 241b may not be distinguishable. The peripheral wiring lines 241a and the peripheral contact plugs 241b each include a conductive material.

A first peripheral upper insulating film 261 and a second peripheral upper insulating film 262 may be disposed on the peripheral wiring lines 241a and the peripheral contact plugs 241b. The first and second peripheral upper insulating films 261 and 262 may each be formed of an insulating material.

Peripheral connection wirings 243 and peripheral connection vias 242 may be disposed on the peripheral wiring lines 241a. The peripheral connection vias 242 may be disposed within the first peripheral upper insulating film 261. The peripheral connection wirings 243 may be disposed within the second peripheral upper insulating film 262.

The peripheral connection wirings 243 and the peripheral connection vias 242 may be connected to the peripheral wiring lines 241a. The peripheral connection vias 242 may connect the peripheral wiring lines 241a and the peripheral connection wirings 243. The peripheral connection wirings 243 and the peripheral connection vias 242 each include a conductive material. The peripheral connection wirings 243 and the peripheral connection vias 242 are illustrated as being different films, but the present disclosure is not limited thereto. In some embodiments, the boundaries between the peripheral connection wirings 243 and the peripheral connection vias 242 may not be distinguishable.

Peripheral connection wirings 243 disposed at a single metal level are illustrated as being arranged on the peripheral wiring lines 241a, but the present disclosure is not limited thereto. In some other embodiments, different from what is illustrated, multiple peripheral connection wirings 243 disposed at different metal levels may be arranged on the peripheral wiring line 241a.

A first interlayer insulating film 263 may be disposed on the peripheral connection wirings 243. The first interlayer insulating film 263 may include an insulating material.

The data storage patterns DSP may be disposed on the first interlayer insulating film 263. The first interlayer insulating film 263 may be disposed between the data storage patterns DSP and the peripheral connection wirings 243.

The data storage patterns DSP may be electrically connected respectively to first channel patterns AP1 and second channel patterns AP2. As illustrated in FIG. 2, the data storage patterns DSP may be arranged in a matrix form along a first direction DR1 and a second direction DR2.

Here, the first and second directions DR1 and DR2 may be orthogonal to the third direction DR3. The first direction DR1 may intersect the second direction DR2. For example, the third direction DR3 may be the thickness direction of the substrate 100. In other words, the third direction DR3 may be perpendicular to the upper surface of the substrate 100. The first and second directions DR1 and DR2 may be parallel to the upper surface of the substrate 100.

For example, the data storage patterns DSP may be capacitors. The data storage patterns DSP may include a capacitor dielectric film 253, which is interposed between storage electrodes 251 and plate electrodes 255. From a planar perspective, the storage electrodes 251 may have various shapes such as circular, elliptical, rectangular, square, rhombic, and hexagonal. The storage electrodes 251 may penetrate (i.e., extend into) a first etch stop film 247. The first etch stop film 247 may be formed of an insulating material.

The storage electrodes 251 and the plate electrodes 255 may each include at least one of, for example, conductive semiconductor material, conductive metal nitride, conductive metal silicon nitride, metal carbonitride, conductive metal silicide, conductive metal oxide, or a metal. The capacitor dielectric film 253 may include at least one of a ferroelectric material, an antiferroelectric material, or a paraelectric material. For example, the capacitor dielectric film 253 may include one of a ferroelectric material, an antiferroelectric material, a paraelectric material, a combination of the ferroelectric and antiferroelectric materials, a combination of the ferroelectric and paraelectric materials, a combination of the paraelectric and antiferroelectric materials, or a combination of the ferroelectric, antiferroelectric, and paraelectric materials.

In some other embodiments, the data storage patterns DSP may be variable resistance patterns that can switch between two resistance states in response to electrical pulses applied to memory elements. For example, the data storage patterns DSP may include a phase-change material that changes its crystalline state based on the amount of current, a perovskite compound, transition metal oxide, a magnetic material, a ferromagnetic material, or an antiferromagnetic material.

The contact patterns BC may be disposed on the data storage patterns DSP. The contact patterns BC may be disposed on the storage electrodes 251. The storage electrodes 251 may contact the contact patterns BC. From a planar perspective, the contact patterns BC may have various shapes such as circular, elliptical, rectangular, square, rhombic, and hexagonal.

A contact separation insulating film 235 may be disposed on the first etch stop film 247. The contact separation insulating film 235 may be disposed between the contact patterns BC. From a planar perspective, the contact patterns BC may be arranged in a matrix form along the first and second directions DR1 and DR2. The contact separation insulating film 235 may be formed of an insulating material.

Each of the contact patterns BC may include a first surface BC_S1 and a second surface BC_S2 that are opposite to each other in the third direction DR3. Each of the contact patterns BC may also include sidewalls that connect the first and second surfaces BC_S1 and BC_S2.

The first surfaces BC_S1 of the contact patterns BC may face the data storage patterns DSP. The data storage patterns DSP may be connected to the first surfaces BC_S1 of the contact patterns BC. The storage electrodes 251 may contact the first surfaces BC_S1 of the contact patterns BC.

The contact separation insulating film 235 may be on (e.g., may cover or overlap) the sidewalls of the contact patterns BC. For example, the contact separation insulating film 235 may be on (e.g., may cover or overlap) the entire sidewalls of the contact patterns BC.

The data storage patterns DSP may completely or partially overlap with the contact patterns BC in the third direction DR3. The data storage patterns DSP may contact all or parts of the first surfaces BC_S1 of the contact patterns BC. As used herein, “an element A overlaps with an element B in a direction X” (or similar language) means that there is at least one straight line that extends in the direction X and intersects both the elements A and B.

The contact patterns BC may each include a lower portion BC_BP and an upper portion BC_UP. The upper portions BC_UP of the contact patterns BC may protrude in the third direction DR3 from the lower portions BC_BP of the contact patterns BC.

The lower portions BC_BP of the contact patterns BC may include the first surfaces BC_S1 of the contact patterns BC. The storage electrodes 251 may contact the lower portions BC_BP of the contact patterns BC. The upper portions BC_UP of the contact patterns BC may include the second surfaces BC_S2 of the contact patterns BC.

In a cross-sectional view taken along the second direction DR2, a width W21, in the second direction DR2, of the lower portions BC_BP of the contact patterns BC is greater than a width W22, in the second direction DR2, of the upper portions BC_UP of the contact patterns BC. For example, the contact patterns BC may have an “L” shape. From a cross-sectional perspective (i.e., in a cross-sectional view), the contact patterns BC may each include first and second sidewalls that are opposite to each other in the second direction DR2. The first sidewalls of the contact patterns BC may have a rectilinear shape, while the second sidewalls of the contact patterns BC may have a stepped shape.

The contact patterns BC include a conductive material. For example, the contact patterns BC may include at least one of doped polysilicon, conductive metal nitride, conductive metal silicon nitride, metal carbonitride, conductive metal silicide, conductive metal oxide, a 2D material, a metal, or a metal alloy.

Protruding insulating patterns 175 may be disposed on the contact patterns BC and the contact separation insulating film 235. A second etch stop film 173 may be disposed between the protruding insulating patterns 175 and the contact separation insulating film 235.

The protruding insulating patterns 175 may include upper protruding insulating patterns 175U and lower protruding insulating patterns 175B. The lower protruding insulating patterns 175B may be disposed between the upper protruding insulating patterns 175U and the contact patterns BC, and between the upper protruding insulating patterns 175U and the contact separation insulating film 235. The lower protruding insulating patterns 175B may be disposed between the upper protruding insulating patterns 175U and the second etch stop film 173. The upper protruding insulating patterns 175U may include upper surfaces 175_US of the protruding insulating patterns 175.

The upper protruding insulating patterns 175U and the lower protruding insulating patterns 175B may each be formed of an insulating material. The upper protruding insulating patterns 175U and the lower protruding insulating patterns 175B may include different insulating materials. In the semiconductor memory device according to some embodiments, the upper protruding insulating patterns 175U may include silicon nitride, and the lower protruding insulating patterns 175B may include silicon oxide.

The second etch stop film 173 may be formed of an insulating material. The second etch stop film 173 may include a material having an etch selectivity with respect to the lower protruding insulating patterns 175B. In some other embodiments, different from what is illustrated, the second etch stop film 173 may not be disposed between the lower protruding insulating patterns 175B and the contact separation insulating film 235.

The protruding insulating patterns 175 are illustrated as having a double-layer structure, but the present disclosure is not limited thereto. In some other embodiments, different from what is illustrated, for example, the protruding insulating pattern 175 may have a single-layer structure. If the protruding insulating patterns 175 have a single-layer structure, the protruding insulating patterns 175 may include silicon oxide, but the present disclosure is not limited thereto. In some further embodiments, in another example, the protruding insulating patterns 175 may have a triple (or more)-layer structure. In this example, the protruding insulating patterns 175 may have a laminated insulating film structure where silicon oxide, silicon nitride, and silicon oxide are stacked, but the present disclosure is not limited thereto.

The protruding insulating patterns 175 may include a plurality of channel trenches CH_T. For example, the channel trenches CH_T may be formed in the protruding insulating patterns 175. The channel trenches CH_T may extend in the first direction DR1. Each pair of adjacent channel trenches CH_T may be spaced apart in the second direction DR2.

The channel trenches CH_T may expose the contact patterns BC. The second surfaces BC_S2 of the contact patterns BC may be covered by the protruding insulating patterns 175. The second surfaces BC_S2 of the contact patterns BC may not be exposed by the channel trenches CH T. Portions of the contact patterns BC exposed by the channel trenches CH_T may be portions of the lower portions BC_BP of the contact patterns BC.

The bottom surfaces of the channel trenches CH_T may be defined by the contact patterns BC and the contact separation insulating film 235. The bottom surfaces of the channel trenches CH_T may be uneven. Based on the first surfaces BC_S1 of the contact patterns BC, the portions of the bottom surfaces of the channel trenches CH_T defined by the contact patterns BC may be lower than the portions of the bottom surfaces of the channel trenches CH_T defined by the contact separation insulating film 235. The bottom surfaces of the portions of the bottom surfaces of the channel trenches CH_T defined by the contact patterns BC may be defined by the lower portions BC_BP of the contact patterns BC.

The contact patterns BC may include first regions that overlap with the channel trenches CH_T in the third direction DR3, and second regions that do not overlap with the channel trenches CH_T in the third direction DR3. The thickness of the first regions of the contact patterns BC in the third direction DR3 may be smaller than the thickness of the second regions of the contact patterns BC in the third direction DR3.

The sidewalls of the channel trenches CH_T may be defined by the lower protruding insulating patterns 175B, the upper protruding insulating patterns 175U, the second etch stop film 173, and the upper portions BC_UP of the contact patterns BC. At least portions of the sidewalls of the channel trenches CH_T may be sidewalls 175SW of the protruding insulating patterns 175. If the second etch stop film 173 is not present, the sidewalls of the channel trenches CH_T may be defined by the lower protruding insulating patterns 175B, the upper protruding insulating patterns 175U, and the upper portions BC_UP of the contact patterns BC.

The first channel patterns AP1 and the second channel patterns AP2 may be disposed on the data storage patterns DSP. The data storage patterns DSP may be disposed between the first channel patterns AP1 and the substrate 100. The data storage patterns DSP may be disposed between the second channel patterns AP2 and the substrate 100.

The first channel patterns AP1 and the second channel patterns AP2 may be disposed on the contact patterns BC. The first channel patterns AP1 and the second channel patterns AP2 may be connected to the respective contact patterns BC. The first channel patterns AP1 and the second channel patterns AP2 may be in contact with the contact patterns BC.

The first channel patterns AP1 may be spaced apart from one another in the first direction DR1. The first channel patterns AP1 may be spaced apart at regular intervals. The second channel patterns AP2 may be spaced apart from one another in the first direction DR1. The second channel patterns AP2 may be spaced apart at regular intervals. The first channel patterns AP1 may be spaced apart from the second channel patterns AP2 in the second direction DR2. The first channel patterns AP1 and the second channel patterns AP2 may be arranged two-dimensionally along the first and second directions DR1 and DR2.

The first channel patterns AP1 and the second channel patterns AP2 may be disposed within the channel trenches CH_T that extend in the first direction DR1. A plurality of first channel patterns AP1 may be disposed within a single channel trench CH_T. A plurality of second channel patterns AP2 may be disposed within a single channel trench CH_T.

Referring to FIG. 5, the first channel patterns AP1 and the second channel patterns AP2 may each include a first surface AP_S1 and a second surface AP_S2 that are opposite to each other in the third direction DR3. The first surfaces AP_S1 of the first channel patterns AP1 and the first surfaces AP_S1 of the second channel patterns AP2 may face the contact patterns BC. The first surfaces AP_S1 of the first channel patterns AP1 and the first surfaces AP_S1 of the second channel patterns AP2 may be connected to the contact patterns BC. The second surfaces AP_S2 of the first channel patterns AP1 and the second surfaces AP_S2 of the second channel patterns AP2 may face the bitlines BL. The second surfaces AP_S2 of the first channel patterns AP1 and the second surfaces AP_S2 of the second channel patterns AP2 may be connected to the bitlines BL. From a cross-sectional perspective, the second surfaces AP_S2 of the first channel patterns AP1 and the second surfaces AP_S2 of the second channel patterns AP2 may be the uppermost surfaces of the first channel patterns AP1 and the uppermost surfaces of the second channel patterns AP2, respectively.

The first channel patterns AP1 and the second channel patterns AP2 may each include a first sidewall AP_SS1 and a second sidewall AP_SS2 that are opposite to each other in the second direction DR2. The first sidewalls AP_SS1 of the first channel patterns AP1 and the first sidewalls AP_SS1 of the second channel patterns AP2 may face the protruding insulating patterns 175. The second sidewalls AP_SS2 of the first channel patterns AP1 may face the second sidewalls AP_SS2 of the second channel patterns AP2.

The second sidewalls AP_SS2 of the first channel patterns AP1 may be adjacent to first wordlines WL1. The second sidewalls AP_SS2 of the second channel patterns AP2 may be adjacent to second wordlines WL2.

Referring to FIG. 5, a width W11, in the second direction DR2, of the first surfaces AP_S1 of the channel patterns AP1 and AP2 may be the same as (i.e., may be equal to) a width W12, in the second direction DR2, of the second surfaces AP_S2 of the channel patterns AP1 and AP2. The first channel patterns AP1 and the second channel patterns AP2 may both have an “I” shape.

The first channel patterns AP1 and the second channel patterns AP2 may be disposed on the lower portions BC_BP of the contact patterns BC (e.g., see FIG. 6). The first surfaces AP_S1 of the channel patterns AP1 and AP2 may be in contact with the lower portions BC_BP of the contact patterns BC.

Portions of the first sidewalls AP_SS1 of the channel patterns AP1 and AP2 may be in contact with the contact patterns BC. The first sidewalls AP_SS1 of the channel patterns AP1 and AP2 may be in contact with the upper portions BC_UP of the contact patterns BC (e.g., see FIG. 6).

The first channel patterns AP1 and the second channel patterns AP2 may be in contact with both the lower portions BC_BP and the upper portions BC_UP of the contact patterns BC. Referring to FIG. 5, a contact length (W11+L1) between the channel patterns AP1 and AP2 and the contact patterns BC is greater than the width W11, in the second direction DR2, of the first surfaces AP_S1 of the channel patterns AP1 and AP2. In other words, in a cross-sectional view, a length (W11+L1) of an interface where the channel patterns AP1 and AP2 are in contact with the contact patterns BC is greater than the width W11, in the second direction DR2, of the first surfaces AP_S1 of the channel patterns AP1 and AP2.

As the first sidewalls AP_SS1 of the channel patterns AP1 and AP2 are in contact with the contact patterns BC, the contact length (W11+L1) between the channel patterns AP1 and AP2 and the contact patterns BC may be increased. As a result, the contact resistance between the channel patterns AP1 and AP2 and the contact patterns BC may be reduced. This contact resistance reduction may enhance the performance and reliability of the semiconductor memory device according to some embodiments.

Referring to FIGS. 1 through 6, the first channel patterns AP1 and the second channel patterns AP2 may each include an oxide semiconductor material. The first channel patterns AP1 and the second channel patterns AP2 may include, for example, a metal oxide. For example, the first channel patterns AP1 and the second channel patterns AP2 may be amorphous metal oxide films. In another example, the first channel patterns AP1 and the second channel patterns AP2 may be polycrystalline metal oxide films. In yet another example, the first channel patterns AP1 and the second channel patterns AP2 may be a combination of amorphous metal oxide films and polycrystalline metal oxide films. In still another example, the first channel patterns AP1 and the second channel patterns AP2 may be c-axis aligned crystalline (CAAC) metal oxide films.

The first channel patterns AP1 and the second channel patterns AP2 may include, for example, indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, or In—Hf—Al—Zn-based oxide, but the present disclosure is not limited thereto.

Here, In—Ga—Zn-based oxide refers to an oxide having In, Ga, and Zn as its main components, but not necessarily the ratio of In, Ga, and Zn. For example, the channel patterns AP1 and AP2 may include InₓGa_{y}Zn_{z}O. IGZO (In:Ga:Zn=1:1:1) with In, Ga, and Zn included in the same ratios may be an In—Ga—Zn-based oxide. Ga-rich IGZO has a higher Ga ratio and a lower In ratio than IGZO (In:Ga:Zn=1:1:1). Ga-rich IGZO may also be an In—Ga—Zn-based oxide. Additionally, In-rich IGZO has a higher In ratio and a lower Ga ratio than IGZO (In:Ga:Zn=1:1:1). In-rich IGZO may also be an In—Ga—Zn-based oxide.

The first channel patterns AP1 and the second channel patterns AP2 have been described above as including IGZO, but the present disclosure is not limited thereto. The above description may also be applicable if the first channel patterns AP1 and the second channel patterns AP2 each include a ternary or higher metal oxide. Additionally, if the first channel patterns AP1 and the second channel patterns AP2 include an In—Ga—Zn-based oxide, the first channel patterns AP1 and the second channel patterns AP2 may further include a doped metal element other than In, Ga, and Zn.

The first wordlines WL1 may be disposed on the first channel patterns AP1. The second wordlines WL2 may be disposed on the second channel patterns AP2. The first wordlines WL1 and the second wordlines WL2 may be disposed within the channel trenches CH_T.

The first wordlines WL1 may be disposed on the second sidewalls AP_SS2 of the first channel patterns AP1. The first wordlines WL1 may not be disposed on the first sidewalls AP_SS1 of the first channel patterns AP1. The second wordlines WL2 may be disposed on the second sidewalls AP_SS2 of the second channel patterns AP2. The second wordlines WL2 may not be disposed on the first sidewalls AP_SS1 of the second channel patterns AP2.

The first wordlines WL1 and the second wordlines WL2 may extend in the first direction DR1. The first wordlines WL1 and the second wordlines WL2 may be alternately arranged in the second direction DR2. The first wordlines WL1 are spaced apart from the second wordlines WL2 in the second direction DR2.

The first wordlines WL1 and the second wordlines WL2 are spaced apart from the bitlines BL in the third direction DR3. The first wordlines WL1 and the second wordlines WL2 intersect the bitlines BL. The first wordlines WL1 and the second wordlines WL2 are spaced apart from the contact patterns BC in the third direction DR3. The first wordlines WL1 and the second wordlines WL2 may be disposed between the bitlines BL and the contact patterns BC (e.g., in the third direction DR3).

The first wordlines WL1 and the second wordlines WL2 are disposed between the first channel patterns AP1 and the second channel patterns AP2. The first channel patterns AP1 are closer to the first wordlines WL1 than to the second wordlines WL2. The second channel patterns AP2 are closer to the second wordlines WL2 than to the first wordlines WL1.

The first wordlines WL1 and the second wordlines WL2 may have a width in the second direction DR2. The width of the first wordlines WL1 may differ between the areas where the first channel patterns AP1 and the second channel patterns AP2 overlap in the third direction DR3 and the areas where the first channel patterns AP1 and the second channel patterns AP2 do not overlap in the third direction DR3. Similarly, the width of the second wordlines WL2 may differ between the areas where the first channel patterns AP1 and the second channel patterns AP2 overlap in the third direction DR3 and the areas where the first channel patterns AP1 and the second channel patterns AP2 do not overlap in the third direction DR3.

For example, the first wordlines WL1 and the second wordlines WL2 may each include first portions WLa and second portions WLb (e.g., see FIGS. 2 and 3). The width, in the second direction DR2, of the first portions WLa of the wordlines WL1 and WL2 may be smaller than the width, in the second direction DR2, of the second portions WLb of the wordlines WL1 and WL2. For example, the first portions WLa of the wordlines WL1 and WL2 may be disposed on the first channel patterns AP1 and the second channel patterns AP2.

The first wordlines WL1 and the second wordlines WL2 may each include first portions WLa and second portions WLb that are alternately arranged in the first direction DR1. In the first wordlines WL1, the first channel patterns AP1 may be disposed among (i.e., between) the second portions WLb of the first wordlines WL1 that are adjacent in the first direction DR1. In the second wordlines WL2, the second channel patterns AP2 may be disposed among (i.e., between) the second portions WLb of the second wordlines WL2 that are adjacent in the first direction DR1.

In some other embodiments, different from what is illustrated, the width, in the second direction DR2, of the first portions WLa of the wordlines WL1 and WL2 may be the same as the width, in the second direction DR2, of the second portions WLb of the wordlines WL1 and WL2. In this case, a gate insulating film GOX, which will be described later, may be in (e.g., may fill) the space between each pair of adjacent first channel patterns AP1 in the first direction DR1 and the space between each pair of adjacent second channel patterns AP2 in the first direction DR1.

The first channel patterns AP1 and the second channel patterns AP2 are not disposed below the second portions WLb of the wordlines WL1 and WL2. The height of the first portions WLa of the wordlines WL1 and WL2 may be less than the height of the second portions WLb of the wordlines WL1 and WL2. For example, the height difference between the first portions WLa of the wordlines WL1 and WL2 and the second portions WLb of the wordlines WL1 and WL2 may be equal to the thickness of the channel patterns AP1 and AP2.

The first wordlines WL1 and the second wordlines WL2 may include a conductive material, such as doped polysilicon, conductive metal nitride, conductive metal silicon nitride, metal carbonitride, conductive metal silicide, conductive metal oxide, a 2D material, a metal, or a metal alloy.

The first wordlines WL1 and the second wordlines WL2 may each include a first surface WL SI and a second surface WL_S2 that are opposite to each other in the third direction DR3. The first surfaces WL_S1 of the first wordlines WL1 and the first surfaces WL_S1 of the second wordlines WL2 may face the contact patterns BC.

Referring to FIG. 5, the second surfaces WL S2 of the wordlines WL1 and WL2 may be planar (i.e., flat). In some other embodiments, different from what is illustrated, the second surfaces WL S2 of the wordlines WL1 and WL2 may be convexly rounded. In some further embodiments, the second surfaces WL_S2 of the wordlines WL1 and WL2 may be concavely rounded.

The following description is provided from a cross—sectional perspective, as illustrated in FIGS. 3 and 5. Based on the second surfaces BC_S2 of the contact patterns BC, the second surfaces WL_S2 of the wordlines WL1 and WL2 may be equal to or higher than the second surfaces AP_S2 of the channel patterns AP1 and AP2. A height H13 from the second surfaces BC_S2 of the contact patterns BC to the second surfaces AP_S2 of the channel patterns AP1 and AP2 may be less than or equal to a height H15 from the second surfaces BC S2 of the contact patterns BC to the second surfaces WL_S2 of the wordlines WL1 and WL2.

Based on the second surfaces BC_S2 of the contact patterns BC, the second surfaces AP_S2 of the channel patterns AP1 and AP2 may be lower than the upper surfaces 175_US of the protruding insulating patterns 175. The height H13 from the second surfaces BC_S2 of the contact patterns BC to the second surfaces AP_S2 of the channel patterns AP1 and AP2 is less than a height H11 from the second surfaces BC_S2 of the contact patterns BC to the upper surfaces 175_US of the protruding insulating patterns 175.

From a cross-sectional perspective, as portions of the contact patterns BC may be recessed, forming the upper portions BC_UP of the contact patterns BC (e.g., see FIG. 6), the distance between the wordlines WL1 and WL2 and the contact patterns BC may be increased. This increased distance may help prevent the wordlines WL1 and WL2 from shorting with the contact patterns BC. Consequently, the performance and reliability of the semiconductor memory device according to some embodiments may be improved.

The gate insulating film GOX may be disposed between the first wordlines WL1 and the first channel patterns AP1, and between the second wordlines WL2 and the second channel patterns AP2. The gate insulating film GOX may extend in the first direction DR1 parallel to the first wordlines WL1 and the second wordlines WL2.

The gate insulating film GOX may be disposed on the second sidewalls AP SS2 of the channel patterns AP1 and AP2. The gate insulating film GOX may contact the second sidewalls AP SS2 of the channel patterns AP1 and AP2. The gate insulating film GOX may not contact the first sidewalls AP_SS1 of channel patterns AP1 and AP2.

The gate insulating film GOX may contact the contact patterns BC. For example, the gate insulating film GOX may contact the lower portions BC_BP of the contact patterns BC (e.g., see FIG. 6).

In some other embodiments, different from what is illustrated in FIG. 5, the channel patterns AP1 and AP2 may fully fill the spaces between the upper portions BC_UP of the contact patterns BC and the contact separation insulating film 235. In this case, the gate insulating film GOX may not contact the contact patterns BC.

The gate insulating film GOX may not be disposed between the wordlines WL1 and WL2 and the contact separation insulating film 235. The gate insulating film GOX may not contact the first surfaces WL_S1 of the wordlines WL1 and WL2.

From a cross-sectional perspective, portions of the gate insulating film GOX between the first wordlines WL1 and the first channel patterns AP1 may be separated from portions of the gate insulating film GOX between the second wordlines WL2 and the second channel patterns AP2.

The gate insulating film GOX may include a silicon oxide film, a silicon oxynitride film, a high-k dielectric film with a higher dielectric constant than a silicon oxide film, or a combination thereof. For example, the gate insulating film GOX may include aluminum oxide, but the present disclosure is not limited thereto.

Portions of the gate insulating film GOX may protrude in the third direction DR3 beyond the second surfaces WL_S2 of the wordlines WL1 and WL2. Portions of the gate insulating film GOX may protrude in the third direction DR3 beyond the second surfaces AP S2 of the first channel patterns AP1 and the second surfaces AP_S2 of the second channel patterns AP2.

The height H14 from the second surfaces BC_S2 of the contact patterns BC to an uppermost surface GOX_UUS of the gate insulating film GOX may be greater than the height H13 from the second surfaces BC_S2 of the contact patterns BC to the second surfaces AP_S2 of the channel patterns AP1 and AP2. The height H14 from the second surfaces BC_S2 of the contact patterns BC to the uppermost surface GOX_UUS of the gate insulating film GOX may be greater than the height H15 from the second surfaces BC_S2 of the contact patterns BC to the second surfaces WL_S2 of the wordlines WL1 and WL2.

Gate separation patterns GSS may be disposed between the first wordlines WL1 and the second wordlines WL2 that are adjacent to the first wordlines WL1 in the second direction DR2. The first wordlines WL1 and the second wordlines WL2 may be separated by the gate separation patterns GSS. The gate separation patterns GSS may extend in the first direction DR1 between the first wordlines WL1 and the second wordlines WL2.

The first wordlines WL1 may be disposed between the gate separation patterns GSS and the first channel patterns AP1. The second wordlines WL2 may be disposed between the gate separation patterns GSS and the second channel patterns AP2.

In the semiconductor memory device according to some embodiments, based on the second surfaces BC_S2 of the contact patterns BC, the upper surfaces of the gate separation patterns GSS may be at the same height as the upper surfaces 175_US of the protruding insulating patterns 175. For example, the gate separation patterns GSS may not be disposed on the upper surfaces 175_US of the protruding insulating patterns 175.

The gate separation patterns GSS may be formed of an insulating material. The gate separation patterns GSS are illustrated as being single layers, but the present disclosure is not limited thereto.

The bitlines BL may be disposed on the first channel patterns AP1 and the second channel patterns AP2. The bitlines BL may be connected to the first channel patterns AP1 and the second channel patterns AP2. The bitlines BL may be connected to the vertical portions of the first channel patterns AP1. The bitlines BL may be connected to the vertical portions of the second channel patterns AP2.

The bitlines BL may extend in the second direction DR2. The bitlines BL may be spaced apart from one another in the first direction DR1.

In the semiconductor memory device according to some embodiments, the data storage patterns DSP may be disposed between the peripheral gate structures PG and the bitlines BL.

The bitlines BL may include extension portions BLe and protruding portions BLp. The extension portions BLe of the bitlines BL may extend in the second direction DR2. In the semiconductor memory device according to some embodiments, the width, in the first direction DR1, of the extension portions BLe of the bitlines BL may decrease away from the protruding insulating patterns 175 and the gate separation patterns GSS (e.g., see FIG. 4). For example, the extension portions BLe of the bitlines BL may be formed through a subtractive etching process.

The protruding portions BLp of the bitlines BL may protrude in the third direction DR3. The protruding portions BLp of the bitlines BL may protrude from the extension portions BLe of the bitlines BL toward the first channel patterns AP1. The protruding portions BLp of the bitlines BL may protrude from the extension portions BLe of the bitlines BL toward the second channel patterns AP2.

The protruding portions BLp of the bitlines BL may be connected to the first channel patterns AP1 and the second channel patterns AP2. The protruding portions BLp of the bitlines BL may connect the first channel patterns AP1 and the extension portions BLe of the bitlines BL. The protruding portions BLp of the bitlines BL may connect the second channel patterns AP2 and the extension portions BLe of the bitlines BL. Based on the second surfaces BC S2 of the contact patterns BC, the protruding portions BLp of the bitlines BL may include the lowermost portions of the bitlines BL.

The protruding portions BLp of the bitlines BL may include first sub-protruding portions BLp1 and second sub-protruding portions BLp2.

The first sub-protruding portions BLp1 of the bitlines BL may be connected to the first channel patterns AP1 and the second channel patterns AP2. For example, the first sub-protruding portions BLp1 of the bitlines BL may contact the first channel patterns AP1 and the second channel patterns AP2. For example, from a cross-sectional perspective, the first sub-protruding portions BLp1 of the bitlines BL may be disposed between the gate insulating film GOX and the protruding insulating patterns 175.

The second sub-protruding portions BLp2 of the bitlines BL may be disposed between the first sub-protruding portions BLp1 of the bitlines BL and the extension portions BLe of the bitlines BL. For example, from a cross-sectional perspective, the second sub-protruding portions BLp2 of the bitlines BL may be disposed between the gate separation patterns GSS and the protruding insulating patterns 175.

A width in the second direction DR2 of the second sub-protruding portions BLp2 of the bitlines BL may be greater than a width in the second direction DR2 of the first sub-protruding portions BLp1 of the bitlines BL.

The bitlines BL may include at least one of a doped semiconductor material, conductive metal nitride, conductive metal silicon nitride, metal carbonitride, conductive metal silicide, conductive metal oxide, a 2D material, or a metal. The bitlines BL are illustrated as being single-layered, but the present disclosure is not limited thereto.

In a cross-sectional view such as FIG. 3 or FIG. 5, the height H13 from the second surfaces BC_S2 of the contact patterns BC to the second surfaces AP_S2 of the channel patterns AP1 and AP2 may be the same as the height from the second surfaces BC_S2 of the contact patterns BC to the lowermost portions of the bitlines BL. The height H13 from the second surfaces BC_S2 of the contact patterns BC to the lowermost portions of the bitlines BL may be less than the height H11 from the second surfaces BC_S2 of the contact patterns BC to the upper surfaces 175_US of the protruding insulating patterns 175.

The distance, in the third direction DR3, between the contact patterns BC and the bitlines BL may be the height H13 from the second surfaces BC_S2 of the contact patterns BC to the lowermost portions of the bitlines BL. The height H12 in the third direction DR3 of the channel patterns AP1 and AP2 may be greater than the distance (i.e., the height H13), in the third direction DR3, between the contact patterns BC and the bitlines BL.

In some other embodiments, different from what is illustrated, the protruding portions BLp of the bitlines BL may not include the first sub-protruding portions BLp1. In this case, the second sub-protruding portions BLp2 of the bitlines BL may contact the first channel patterns AP1 and the second channel patterns AP2, and a height H14 from the second surfaces BC_S2 of the contact patterns BC to the uppermost surface GOX_UUS of the gate insulating film GOX may be greater than the height H13 from the second surfaces BC_S2 of the contact patterns BC to the second surfaces AP_S2 of the channel patterns AP1 and AP2.

The extension portions BLe of the bitlines BL may be disposed within a second interlayer insulating film 264. A third interlayer insulating film 265 may be disposed on the bitlines BL and the second interlayer insulating film 264. The second and third interlayer insulating films 264 and 265 may each include an insulating material.

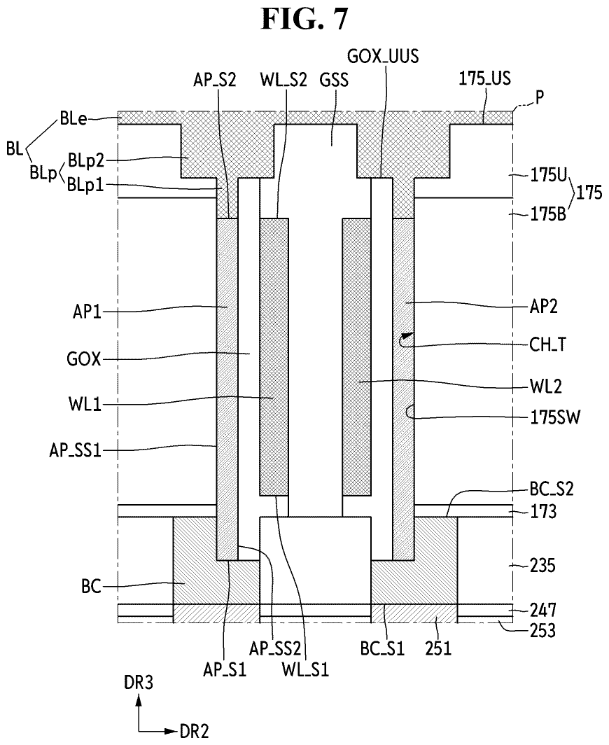

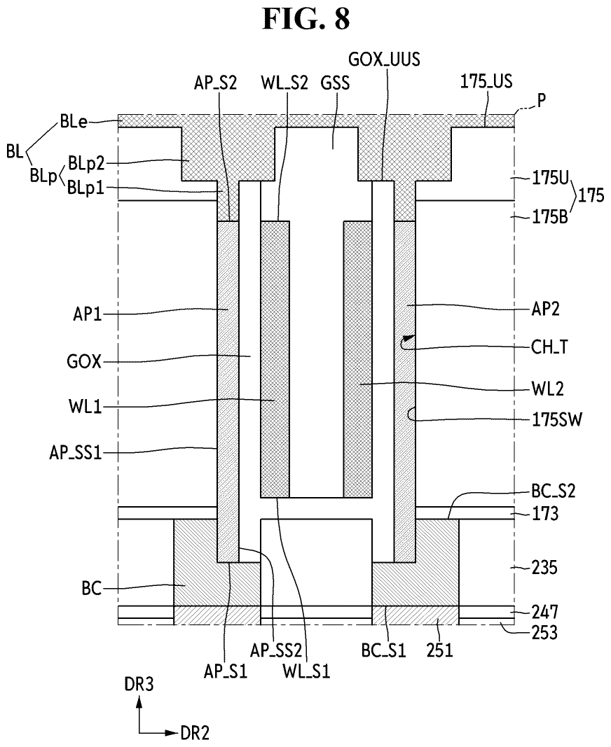

FIGS. 7 and 8 are cross-sectional views that illustrate semiconductor memory devices according to some embodiments. For convenience of explanation, the embodiments of FIGS. 7 and 8 will hereinafter be described, focusing mainly on the differences from what has been described above with reference to FIGS. 1 through 6.

For reference, FIGS. 7 and 8 are enlarged cross-sectional views of parts P (in FIG. 3) of semiconductor memory devices according to some embodiments.

Referring to FIGS. 7 and 8, in the semiconductor memory devices according to some embodiments, a gate insulating film GOX may extend along first surfaces WL_S1 of first and second wordlines WL1 and WL2.

For example, the gate insulating film GOX may be in contact with the first surfaces WL_S1 of the first and second wordlines WL1 and WL2.

Referring to FIG. 7, the portion of the gate insulating film GOX between the first wordline WL1 and a first channel pattern AP1 may be separated from the portion of the gate insulating film GOX between the second wordline WL2 and a second channel pattern AP2.

Referring to FIG. 8, the portion of the gate insulating film GOX between the first wordline WL1 and the first channel pattern AP1 may be directly connected to the portion of the gate insulating film GOX between the second wordline WL2 and the second channel pattern AP2. A portion of the gate insulating film GOX may be disposed between a gate separation pattern GSS and a contact separation insulating film 235.

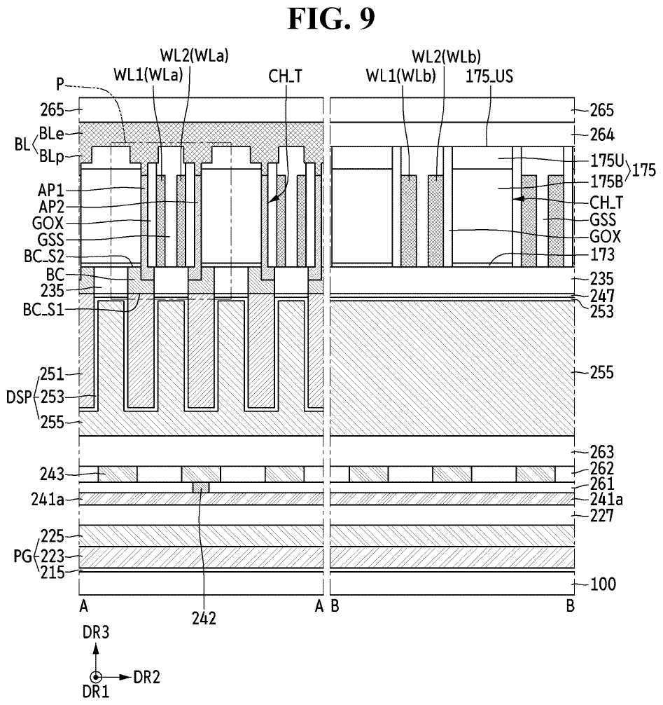

FIGS. 9 through 12 are cross-sectional views that illustrate semiconductor memory devices according to some embodiments. For convenience of explanation, the embodiments of FIGS. 9 through 12 will hereinafter be described, focusing mainly on the differences from what has been described above with reference to FIGS. 1 through 6.

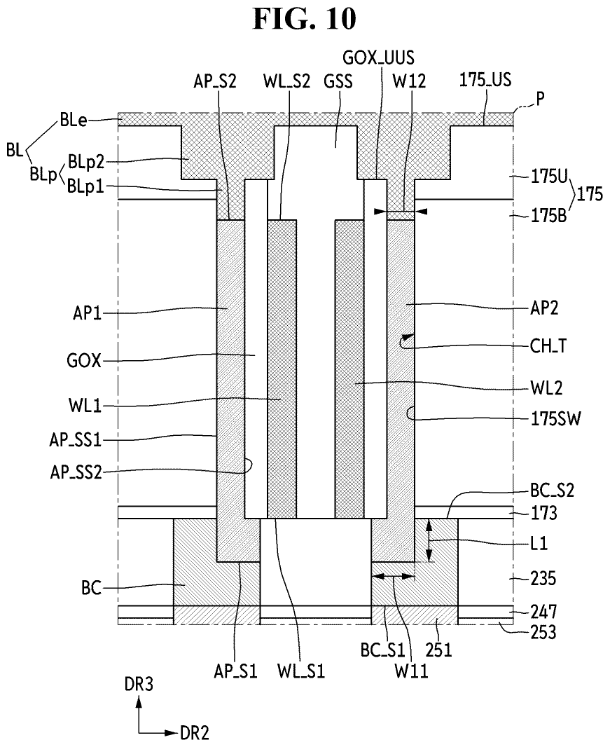

For reference, FIG. 9 corresponds to a cross-sectional view taken along lines A-A and B-B of FIG. 2, and FIGS. 10 through 12 are enlarged views of parts P (in FIG. 9) of semiconductor memory devices according to some embodiments.

Referring to FIGS. 9 through 12, in the semiconductor memory devices according to some embodiments, a width W11 of first surfaces AP_S1 of first and second channel patterns AP1 and AP2 in a second direction DR2 may be greater than a width W12 of second surfaces AP S2 of the first and second channel patterns AP1 and AP2 in the second direction DR2.

For example, first sidewalls AP_SS1 of the first and second channel patterns AP1 and AP2 may have a rectilinear shape, and second sidewalls AP_SS2 of the first and second channel patterns AP1 and AP2 may have a stepped shape. The first and second channel patterns AP1 and AP2 may both have an “L” shape.

From a cross-sectional perspective, the first and second channel patterns AP1 and AP2 may fully fill the spaces between upper portions BC_UP (see FIG. 6) of contact patterns BC and a contact separation insulating film 235. A gate insulating film GOX may not be in contact with the contact patterns BC.

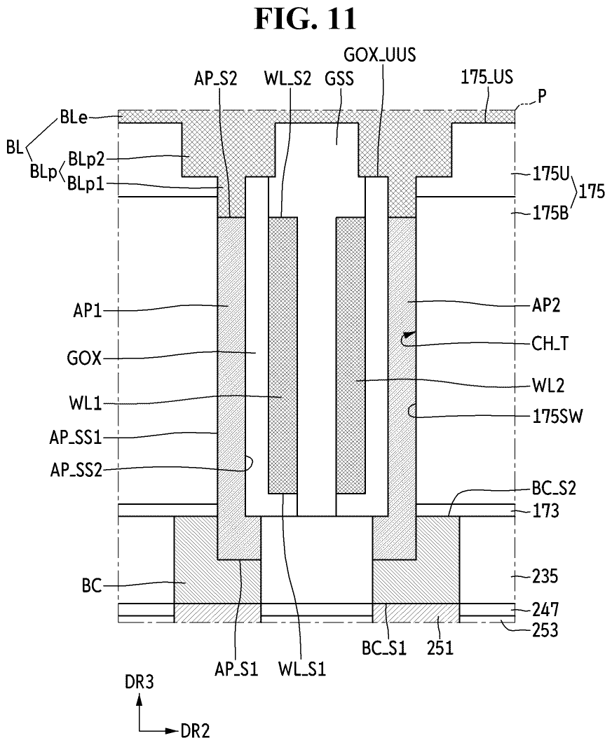

Referring to FIGS. 10 and 11, the portion of the gate insulating film GOX between a first wordline WL1 and the first channel pattern AP1 may be separated from the portion of the gate insulating film GOX between a second wordline WL2 and the second channel pattern AP2.

Referring to FIG. 10, the gate insulating film GOX may not be disposed between the wordlines WL1 and WL2 and the contact separation insulating film 235. The gate insulating film GOX may not extend along first surfaces WL_S1 of the first and second wordlines WL1 and WL2.

Referring to FIG. 11, the gate insulating film GOX may extend along the first surfaces WL_S1 of the first and second wordlines WL1 and WL2. For example, the gate insulating film GOX may be in contact with the first surfaces WL_S1 of the first and second wordlines WL1 and WL2.

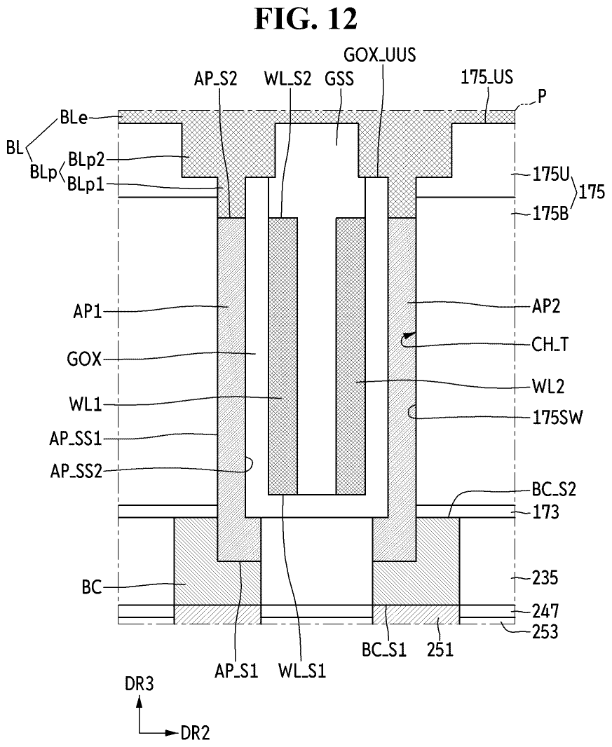

Referring to FIG. 12, the portion of the gate insulating film GOX between the first wordline WL1 and the first channel pattern AP1 may be directly connected to the portion of the gate insulating film GOX between the second wordline WL2 and the second channel pattern AP2.

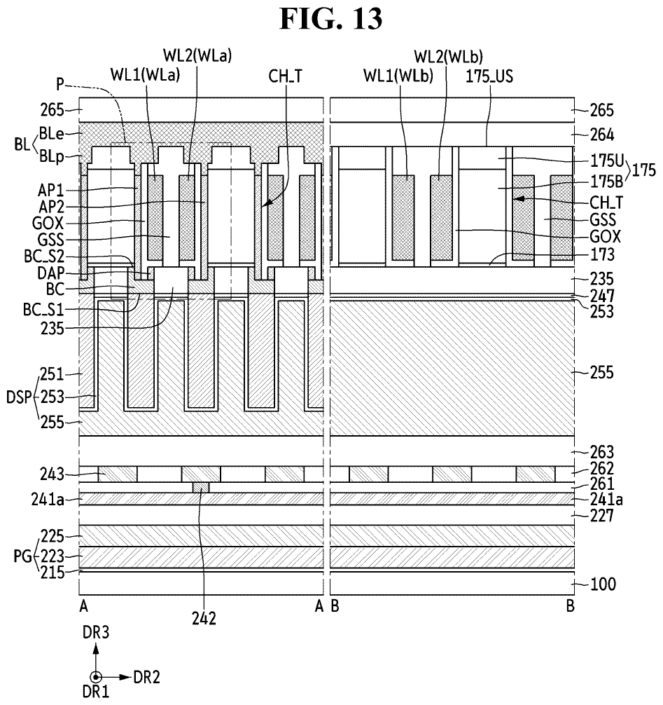

FIGS. 13 through 15 are cross-sectional views that illustrate semiconductor memory devices according to some embodiments. For convenience of explanation, the embodiments of FIGS. 13 through 15 will hereinafter be described, focusing mainly on the differences from what has been described above with reference to FIGS. 1 through 6.

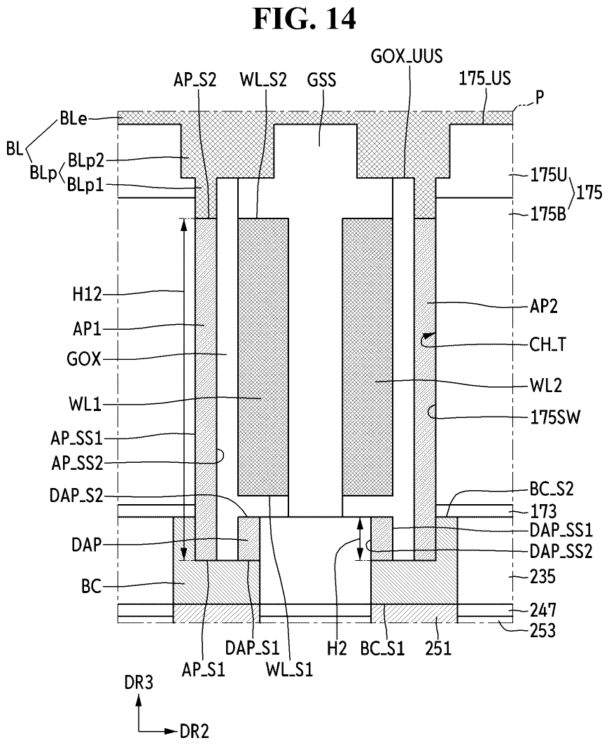

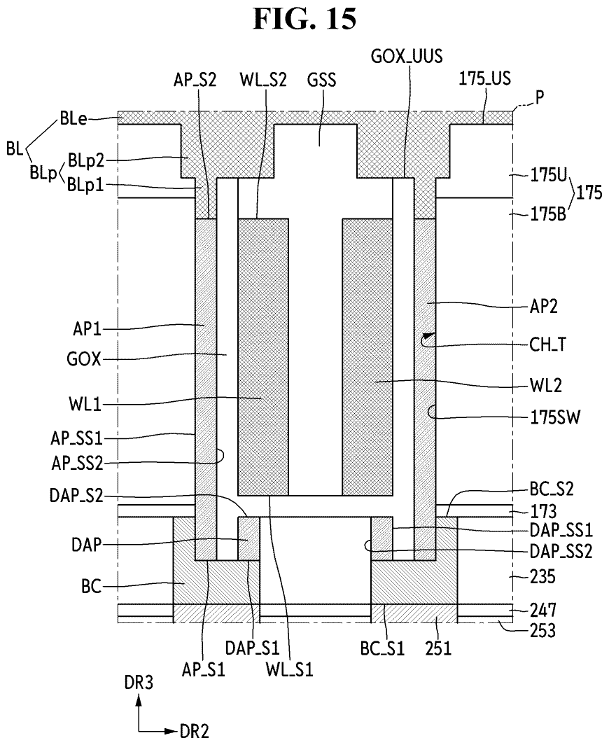

For reference, FIG. 13 corresponds to a cross-sectional view taken along lines A-A and B-B of FIG. 2, and FIGS. 14 and 15 are enlarged cross-sectional views of parts P (in FIG. 13) of semiconductor memory devices according to some embodiments.

Referring to FIGS. 13 through 15, each of the semiconductor memory devices according to some embodiments may further include dummy channel patterns DAP that are disposed on contact patterns BC.

The dummy channel patterns DAP may be connected to the contact patterns BC. The dummy channel patterns DAP may be in contact with the contact patterns BC. For example, the dummy channel patterns DAP may be in contact with lower portions BC_BP of the contact patterns BC (see FIG. 6).

The dummy channel patterns DAP may be spaced apart from a first channel pattern AP1 in a second direction DR2. The dummy channel patterns DAP may be spaced apart from a second channel pattern AP2 in the second direction DR2. The dummy channel patterns DAP may be disposed on second sidewalls AP_SS2 of the first and second channel patterns AP1 and AP2. For example, the dummy channel patterns DAP may be between the contact patterns BC and the wordlines WL1 and WL2 (e.g., in the third direction DR3).

The dummy channel patterns DAP may be spaced apart from each other in a first direction DR1. The dummy channel patterns DAP may also be spaced apart from each other in the second direction DR2. The dummy channel patterns DAP may be arranged two-dimensionally along the first and second directions DR1 and DR2. The dummy channel patterns DAP may be disposed within channel trenches CH T.

The dummy channel patterns DAP may each include a first surface DAP_S1 and a second surface DAP_S2 that are opposite to each other in a third direction DR3. The first surfaces DAP_S1 of the dummy channel patterns DAP may face the contact patterns BC. The first surfaces DAP_S1 of the dummy channel patterns DAP may be connected to the contact patterns BC. The second surfaces DAP_S2 of the dummy channel patterns DAP may face bitlines BL.

The dummy channel patterns DAP may be disposed on lower portions BC_BP of the contact patterns BC (see FIG. 6). The first surfaces DAP_S1 of the dummy channel patterns DAP may be in contact with the lower portions BC_BP of the contact patterns BC.

The dummy channel patterns DAP may each include a first sidewall DAP SS1 and a second sidewall DAP_SS2 that are opposite to each other in the second direction DR2. The first sidewalls DAP_SS1 of the dummy channel patterns DAP may face the second sidewalls AP SS2 of the first and second channel patterns AP1 and AP2. The second sidewalls DAP SS2 of the dummy channel patterns DAP may face a contact separation insulating film 235. For example, the second sidewalls DAP_SS2 of the dummy channel patterns DAP may be in contact with the contact separation insulating film 235.

A height H12 of the first and second channel patterns AP1 and AP2 in the third direction DR3 is different from a height H2 of the dummy channel patterns DAP in the third direction DR3. The height H12 of the first and second channel patterns AP1 and AP2 in the third direction DR3 is greater than the height H2 of the dummy channel patterns DAP in the third direction DR3.

The dummy channel patterns DAP may be channel patterns that are not used for operations of the semiconductor memory devices. The dummy channel patterns DAP may include the same material as the first and second channel patterns AP1 and AP2. For example, the dummy channel patterns DAP may be spaced apart from the bitlines BL (e.g., in the third direction DR3).

The gate insulating film GOX may be disposed between the first channel pattern AP1 and the dummy channel patterns DAP, and between the second channel pattern AP2 and the dummy channel patterns DAP. The gate insulating film GOX may be in (e.g., may fill) the spaces between the second surfaces AP_SS2 of the first and second channel patterns AP1 and AP2 and the first sidewalls DAP_SS1 of the dummy channel patterns DAP.

The gate insulating film GOX may be in contact with the dummy channel patterns DAP. The gate insulating film GOX may be in contact with the first sidewalls DAP_SS1 of the dummy channel patterns DAP.

The gate insulating film GOX may be on (e.g., may cover or overlap) the second surfaces DAP_S2 of the dummy channel patterns DAP. The gate insulating film GOX may be in contact with the second surfaces DAP_S2 of the dummy channel patterns DAP. The gate insulating film GOX may extend along first surfaces WL_S1 of first and second wordlines WL1 and WL2.

Referring to FIG. 14, the portion of the gate insulating film GOX between the first wordline WL1 and the first channel pattern AP1 may be separated from the portion of the gate insulating film GOX between the second wordline WL2 and the second channel pattern AP2.

Referring to FIG. 15, the portion of the gate insulating film GOX between the first wordline WL1 and the first channel pattern AP1 may be directly connected to the portion of the gate insulating film GOX between the second wordline WL2 and the second channel pattern AP2.

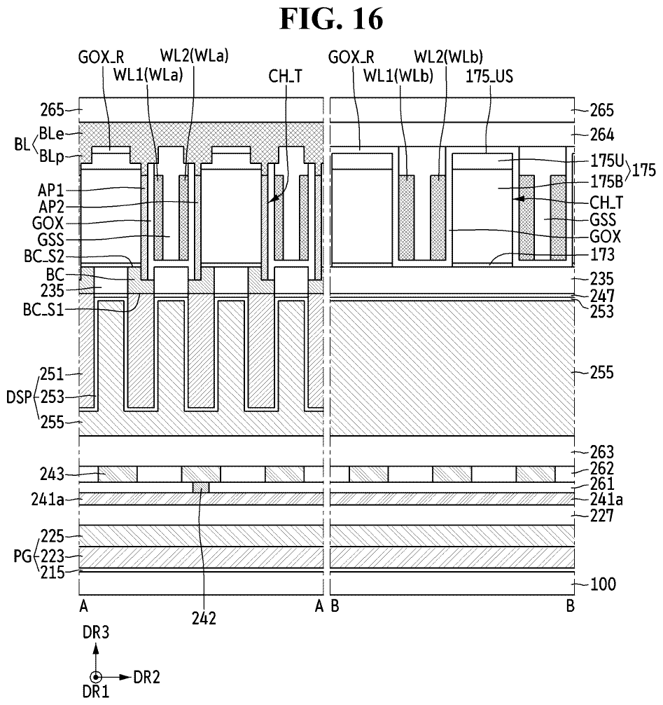

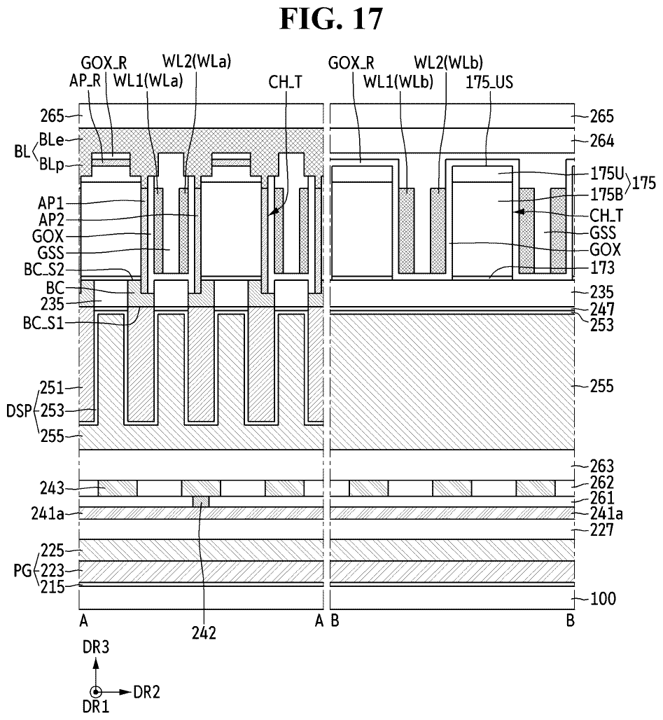

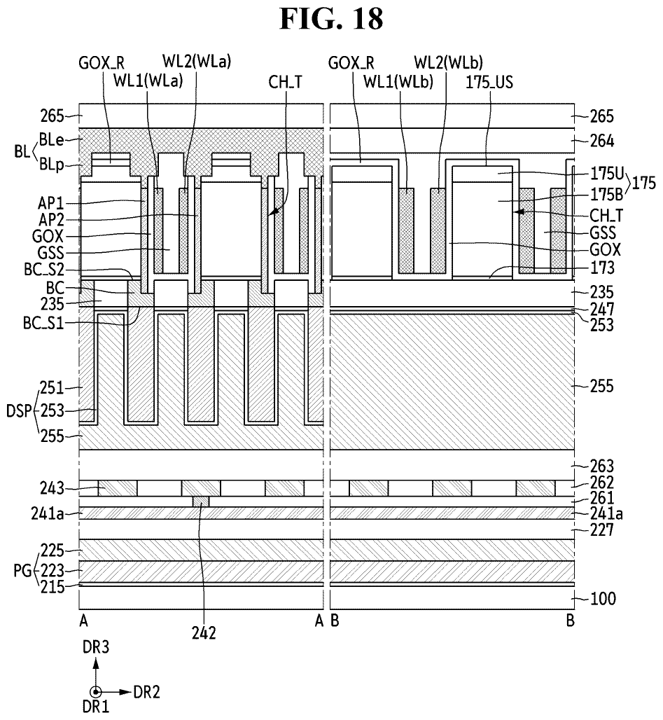

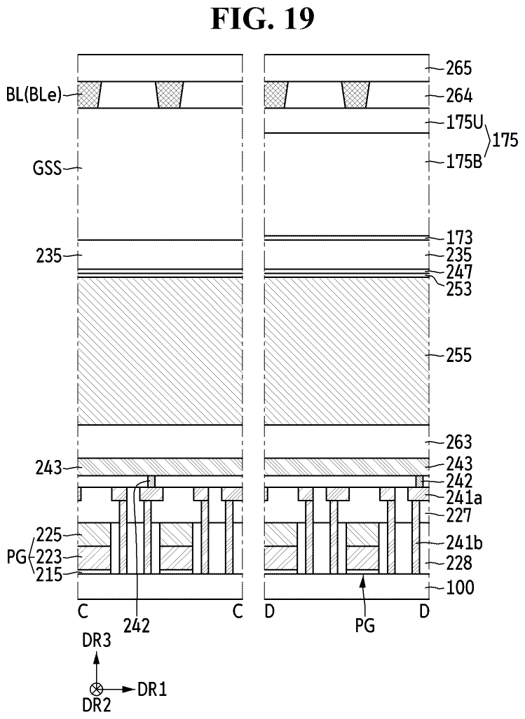

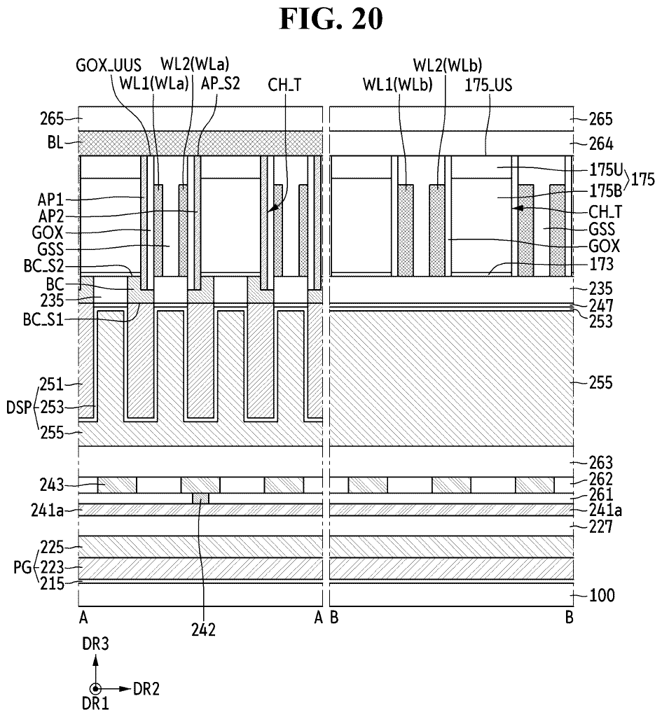

FIG. 16 is a cross-sectional view that illustrates a semiconductor memory device according to some embodiments. FIG. 17 is a cross-sectional view that illustrates a semiconductor memory device according to some embodiments. FIG. 18 is a cross-sectional view that illustrates a semiconductor memory device according to some embodiments. FIG. 19 is a cross-sectional view that illustrates a semiconductor memory device according to some embodiments. FIG. 20 is a cross-sectional view that illustrates a semiconductor memory device according to some embodiments. For convenience of explanation, the embodiments of FIGS. 16 through 20 will hereinafter be described, focusing mainly on the differences from what has been described above with reference to FIGS. 1 through 6.

For reference, FIGS. 16 through 18 and 20 are cross-sectional views taken along lines A-A and B-B of FIG. 2. FIG. 19 is a cross-sectional view taken along lines C-C and D-D of FIG. 2.

Referring to FIGS. 16 through 18, in the semiconductor memory devices according to some embodiments, residual patterns GOX_R of a gate insulating film GOX may be disposed between protruding insulating patterns 175 and bitlines BL.

The residual patterns GOX_R of the gate insulating film GOX may extend along upper surfaces 175_US of protruding insulating patterns 175. The residual patterns GOX_R of the gate insulating film GOX may be directly connected to the gate insulating film GOX. In this case, the residual patterns GOX_R of the gate insulating film GOX may be portions of the gate insulating film GOX disposed on the upper surfaces 175_US of the protruding insulating patterns 175. The gate insulating film GOX may include portions disposed below the upper surfaces 175_US of the protruding insulating patterns 175.

The residual patterns GOX_R of the gate insulating film GOX may include the same material as the gate insulating film GOX.

The portions of the gate insulating film GOX between first wordlines WL1 and first channel patterns AP1 may not be separated from the portions of the gate insulating film GOX between second wordlines WL2 and second channel patterns AP2 by gate separation patterns GSS.

Referring to FIG. 16, the residual patterns GOX_R of the gate insulating film GOX may contact the bitlines BL and the protruding insulating patterns 175.

Referring to FIG. 17, residual patterns AP_R of channel patterns AP1 and AP2 may be disposed between the residual patterns GOX_R of the gate insulating film GOX and the protruding insulating patterns 175. The residual patterns AP_R of the channel patterns AP1 and AP2 may include the same material as the channel patterns AP1 and AP2.

Referring to FIG. 18, portions of gate separation patterns GSS may be disposed on upper surfaces 175_US of protruding insulating patterns 175.

Referring to FIG. 19, a width, in a first direction DR1, of extension portions BLe of bitlines BL may increase away from protruding insulating patterns 175 and gate separation patterns GSS.

For example, the extension portions BLe of the bitlines BL may be formed through a damascene process.

Referring to FIG. 20, in the semiconductor memory device according to some embodiments, the height from second surfaces BC_S2 of contact patterns BC to second surfaces AP_S2 of channel patterns AP1 and AP2 may be the same as the height from the second surfaces BC_S2 of the contact patterns BC to an uppermost surface GOX_UUS of the gate insulating film GOX. In other words, a height of the first and second channel patterns AP1 and AP2 in the third direction DR3 may be the same as a height of the gate insulating film GOX in the third direction DR3.

For example, bitlines BL may include extension portions BLe (see FIG. 3) extending in a second direction DR2, and may not include protruding portions BLp (see FIG. 3) protruding in a third direction DR3.

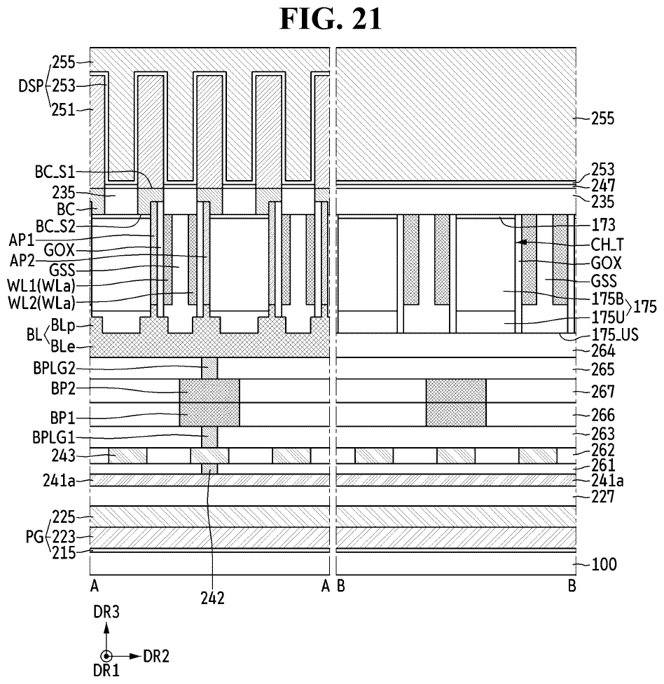

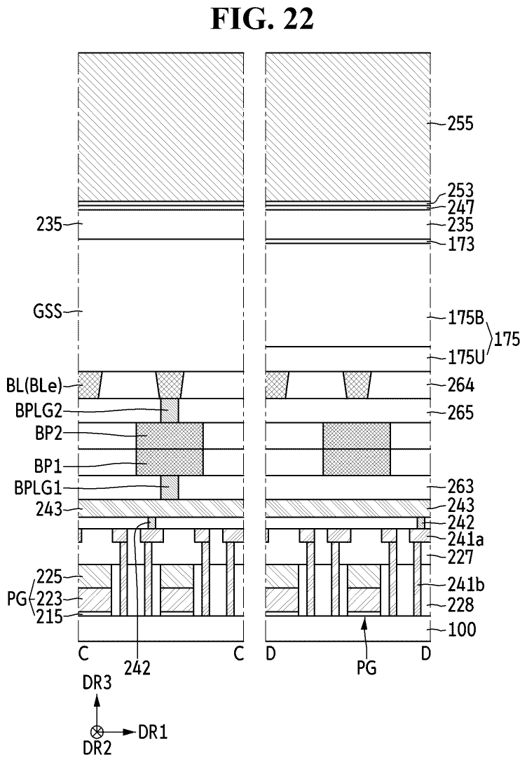

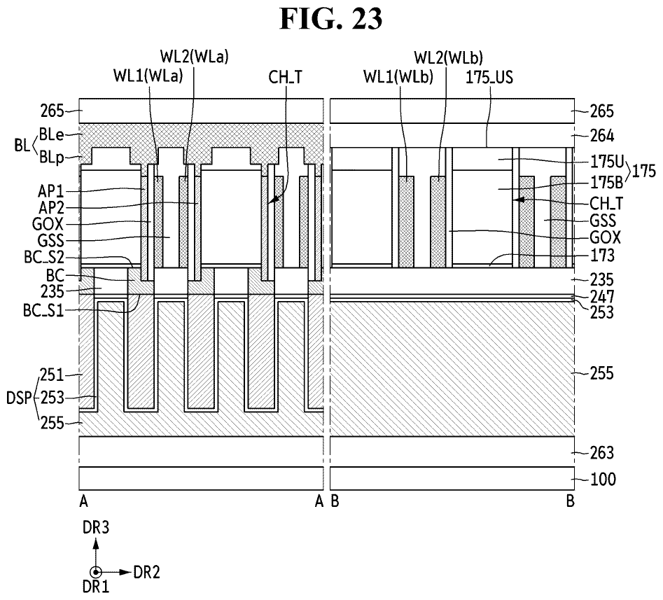

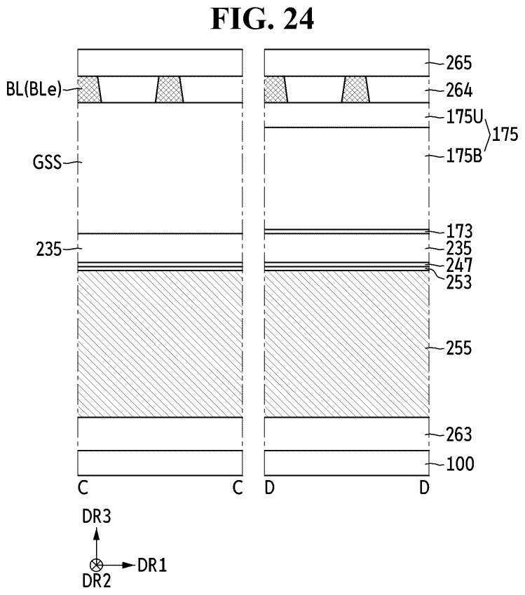

FIGS. 21 and 22 are cross-sectional views that illustrate a semiconductor memory device according to some embodiments. FIGS. 23 and 24 are cross-sectional views that illustrate a semiconductor memory device according to some embodiments. For convenience of explanation, the embodiments of FIGS. 21 through 24 will hereinafter be described, focusing mainly on the differences from what has been described above with reference to FIGS. 1 through 6.

For reference, FIGS. 21 and 23 are cross-sectional views corresponding to lines A-A and B-B of FIG. 2. FIGS. 22 and 24 are cross-sectional views corresponding to lines C-C and D-D of FIG. 2.

Referring to FIGS. 21 and 22, the semiconductor memory device according to some embodiments may further include first bonding pads BP1 and second bonding pads BP2.

The first bonding pads BP1 may be disposed on peripheral gate structures PG. The first bonding pads BP1 may be connected to peripheral connection wirings 243.

First pad plugs BPLG1 may be disposed between the first bonding pads BP1 and the peripheral connection wirings 243. The first pad plugs BPLG1 may connect the first bonding pads BP1 and the peripheral connection wirings 243.

The first pad plugs BPLG1 may be disposed within a first interlayer insulating film 263. The first bonding pads BP1 may be disposed within a fourth interlayer insulating film 266. The fourth interlayer insulating film 266 may be disposed on the first interlayer insulating film 263.

The second bonding pads BP2 may be disposed on the first bonding pads BP1. The second bonding pads BP2 may be connected to the first bonding pads BP1. The second bonding pads BP2 may contact the first bonding pads BP1.

Second pad plugs BPLG2 may connect the bitlines BL to the second bonding pads BP2. Although not illustrated, the second pad plugs BPLG2 may connect first wordlines WL1 and second wordlines WL2 to the second bonding pads BP2.

The second pad plugs BPLG2 may be disposed within a third interlayer insulating film 265. The second bonding pads BP2 may be disposed within a fifth interlayer insulating film 267. The fifth interlayer insulating film 267 may be disposed between the third interlayer insulating film 265 and the fourth interlayer insulating film 266. The fourth interlayer insulating film 266 may be disposed between the fifth interlayer insulating film 267 and the first interlayer insulating film 263.

The first pad plugs BPLG1 and the second pad plugs BPLG2 may each include a conductive material containing metal. The first bonding pads BP1 and the second bonding pads BP2 may each include a conductive material containing metal. The fourth and fifth interlayer insulating films 266 and 267 may each include an insulating material.

Although not illustrated, a bonding insulating film may be disposed along the boundaries of the first bonding pads BP1 and the second bonding pads BP2. For example, the bonding insulating film may include silicon carbonitride (SiCN). In another example, the bonding insulating film may include silicon oxide.

In the semiconductor memory device according to some embodiments, the bitlines BL may be disposed between data storage patterns DSP and peripheral gate structures PG.

Referring to FIGS. 23 and 24, in the semiconductor memory device according to some embodiments, peripheral gate structures PG may not be disposed in a cell array region CAR of a substrate 100 (see FIG. 1).

The peripheral gate structures PG may be disposed only in a peripheral circuit region PCR of the substrate 100 (see FIG. 1).

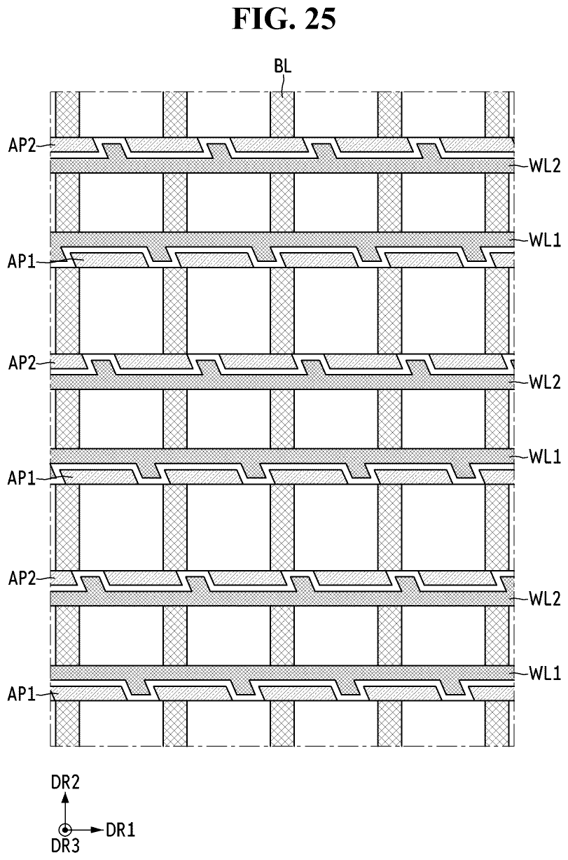

FIGS. 25 through 28 are layout views that illustrate semiconductor memory devices according to some embodiments. For convenience of explanation, the embodiments of FIGS. 25 through 28 will hereinafter be described, focusing mainly on the differences from what has been described above with reference to FIGS. 1 through 6.

Referring to FIG. 25, in the semiconductor memory device according to some embodiments, first channel patterns AP1 and second channel patterns AP2 may be alternately arranged in a diagonal direction relative to a first direction DR1 and a second direction DR2. Here, the diagonal direction may be parallel to the upper surface of a substrate 100 (e.g., see FIG. 3).

The first channel patterns AP1 and the second channel patterns AP2 may be formed twisted in the diagonal direction. From a planar perspective, the first channel patterns AP1 and the second channel patterns AP2 may each have a parallelogram or rhomboid shape.

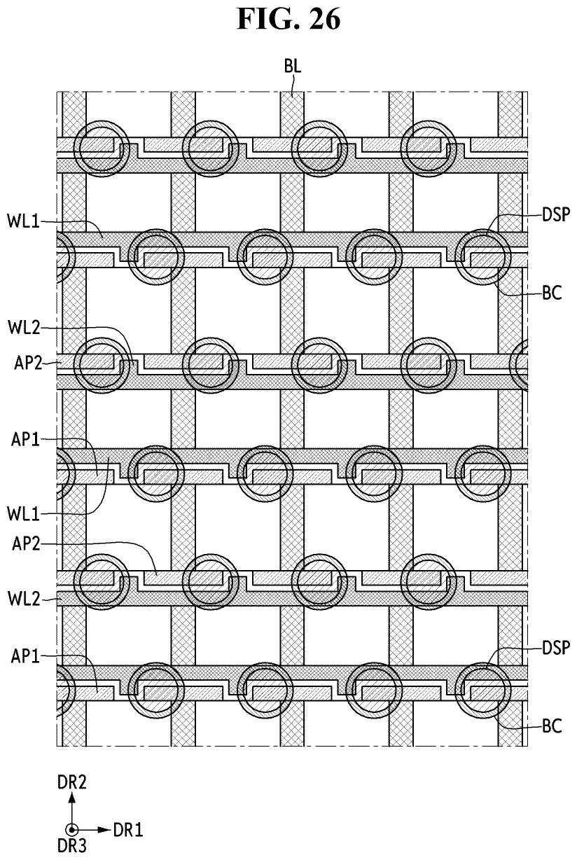

Referring to FIG. 26, in the semiconductor memory device according to some embodiments, contact patterns BC and data storage patterns DSP may be arranged in a zigzag or honeycomb fashion from a planar perspective.

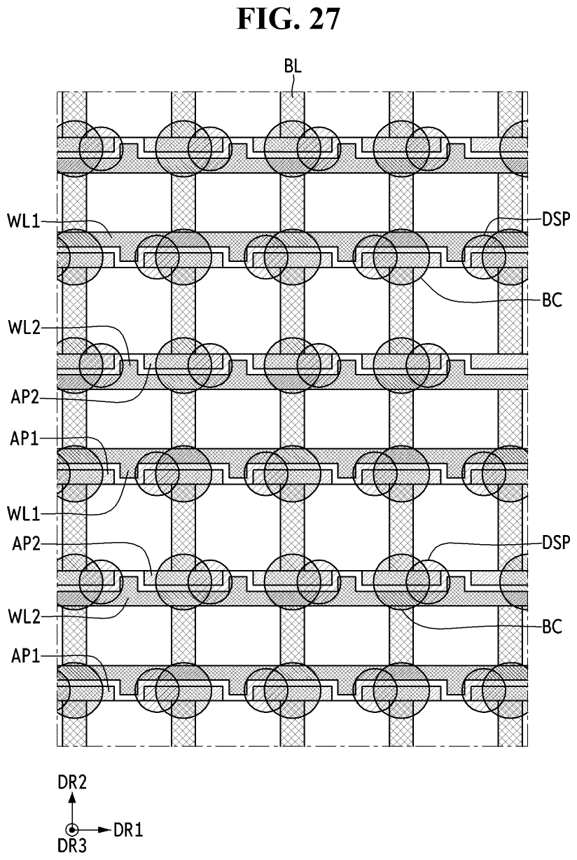

Referring to FIG. 27, in the semiconductor memory device according to some embodiments, data storage patterns DSP may be arranged offset from contact patterns BC from a planar perspective.

The data storage patterns DSP may contact portions of the contact patterns BC.

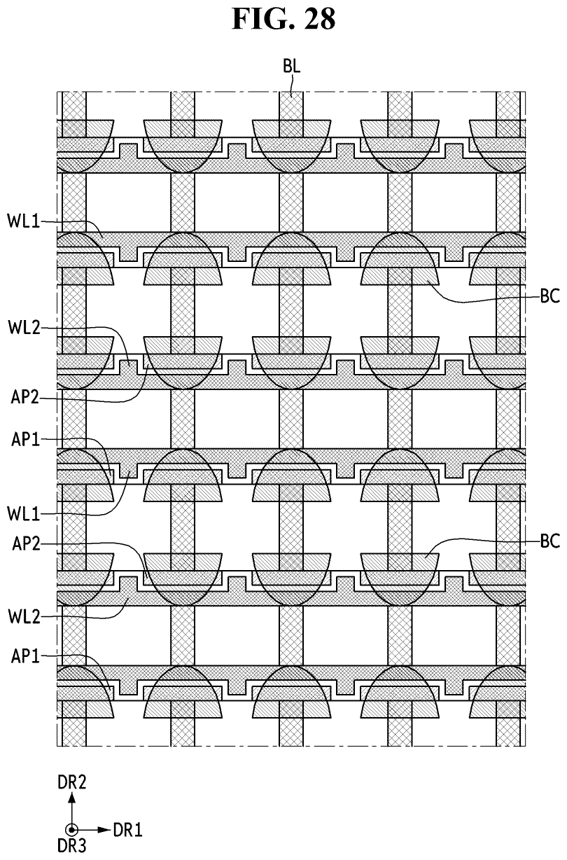

Referring to FIG. 28, in the semiconductor memory device according to some embodiments, contact patterns BC, which are disposed on first channel patterns AP1 and second channel patterns AP2, may have a semicircular or semi-elliptical shape from a planar perspective.

From a planar perspective, the contact patterns BC may be arranged symmetrically to one another.

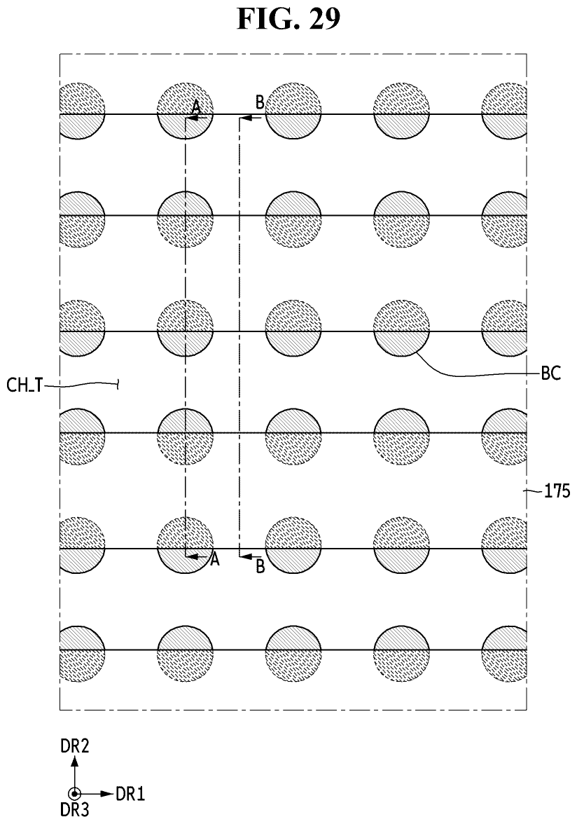

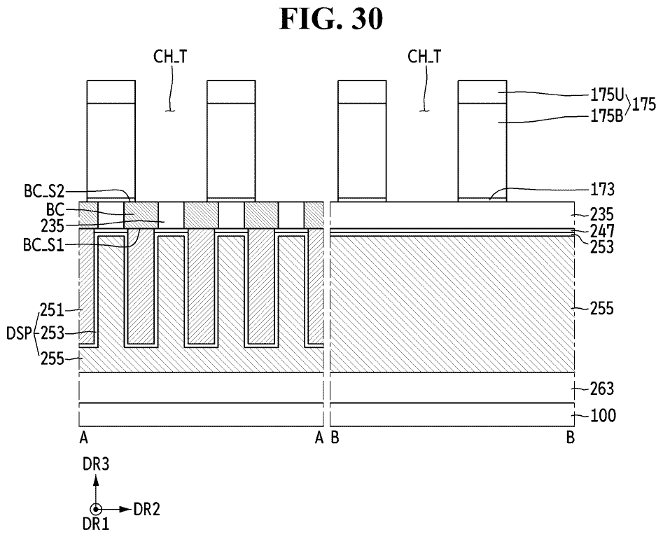

FIGS. 29 through 37 are views that illustrate a method of manufacturing a semiconductor memory device according to some embodiments. For reference, FIG. 29 is a layout view, and FIGS. 30 through 37 are cross-sectional views corresponding to lines A-A and B-B in FIG. 29.

Referring to FIGS. 29 and 30, a contact separation insulating film 235 may be formed on a sub-substrate.

Contact patterns BC may be formed within the contact separation insulating film 235. The contact patterns BC may be formed on the sub-substrate.

Data storage patterns DSP may be formed on the contact patterns BC and the contact separation insulating film 235.

Thereafter, the sub-substrate on which the data storage patterns DSP and the contact patterns BC are formed may be bonded to a substrate 100. The data storage patterns DSP and the substrate 100 may be bonded by a first interlayer insulating film 263.

In some other embodiments, different from what is illustrated, before the bonding of the sub-substrate to the substrate 100, peripheral gate structures PG (see FIG. 3) may be formed on the substrate 100. In this case, the sub-substrate on which the data storage patterns DSP and the contact patterns BC are formed may be bonded to the substrate 100 on which the peripheral gate structures PG are formed.

After the sub-substrate and the substrate 100 are bonded together, the sub-substrate may be removed.

Thereafter, protruding insulating patterns 175 may be formed on the contact patterns BC and the contact separation insulating film 235. Channel trenches CH_T may be formed within the protruding insulating patterns 175. The channel trenches CH_T may extend in a first direction DR1. As a result, the protruding insulating patterns 175, including channel trenches CH_T, may be formed on the contact patterns BC and the contact separation insulating film 235.

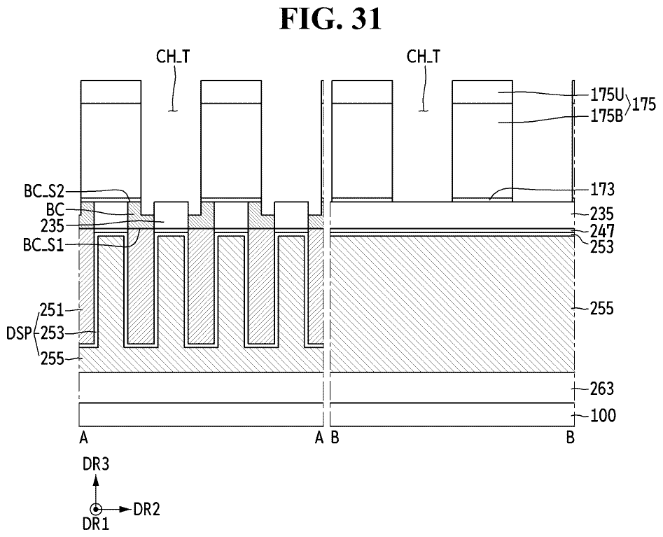

Referring to FIG. 31, portions of the contact patterns BC exposed by the channel trenches CH_T may be removed through an etching process.

In the regions where the contact patterns BC overlap with the channel trenches CH_T in the third direction DR3, the thickness of the contact patterns BC may become thinner. As a result, from a cross-sectional perspective, channel grooves may be formed between the contact patterns BC and the contact separation insulating film 235.

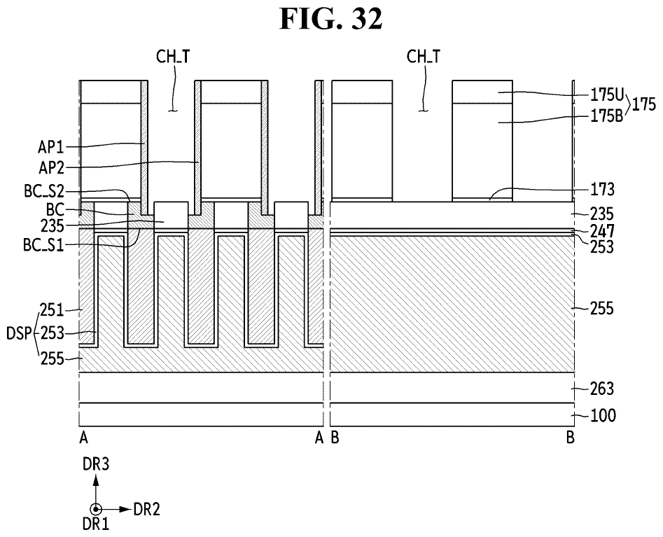

Referring to FIGS. 32 through 34, first channel patterns AP1 and second channel patterns AP2 may be formed along the sidewalls of the channel trenches CH_T.

Specifically, a pre-channel film may be formed along the sidewalls and the bottom surfaces of the channel trenches CH_T. The pre-channel film may also be formed along the upper surfaces of the protruding insulating patterns 175.

Referring to FIG. 32, a mask pattern may be formed on the pre-channel film. The mask pattern may expose portions of the pre-channel film on the bottom surfaces of the channel trenches CH_T. Using the mask pattern as an etching mask, the portions of the pre-channel film on the bottom surface of the channel trench CH_T may be removed. After the removal of the mask pattern, a sacrificial pattern may be formed within the channel trenches CH_T. Once the sacrificial pattern is formed, portions of the pre-channel film on the upper surfaces of the protruding insulating patterns 175 may be exposed. The exposed portions of the pre-channel film on the upper surfaces of the protruding insulating patterns 175 may be removed, forming the first channel patterns AP1 and the second channel patterns AP2. Thereafter, the sacrificial pattern may be removed.

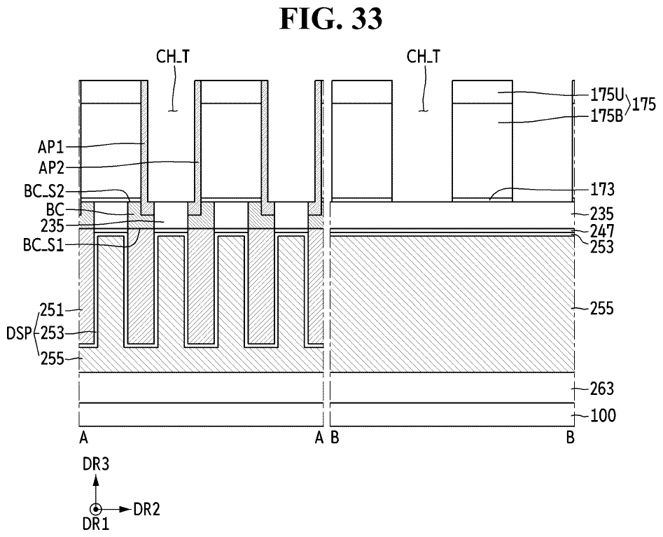

Referring to FIG. 33, the pre-channel film may fully fill the channel grooves between the contact patterns BC and the contact separation insulating film 235. The thickness of the portions of the pre-channel film filling the channel grooves may be greater than the thickness of the portions of the pre-channel film on the upper surface of the contact separation insulating film 235. Thereafter, through an etching process, the portions of the pre-channel film on the upper surfaces of the protruding insulating patterns 175 may be removed. During the removal of the portions of the pre-channel film on the upper surfaces of the protruding insulating patterns 175, the portions of the pre-channel film on the upper surface of the contact separation insulating film 235 may also be removed. Since the thickness of the portions of the pre-channel film filling the channel grooves is greater than the thickness of the portions of the pre-channel film on the upper surface of the contact separation insulating film 235, the portions of the pre-channel film within the channel grooves are not completely removed. As a result, “L”-shaped first channel patterns AP1 and “L”-shaped second channel patterns AP2 may be formed.

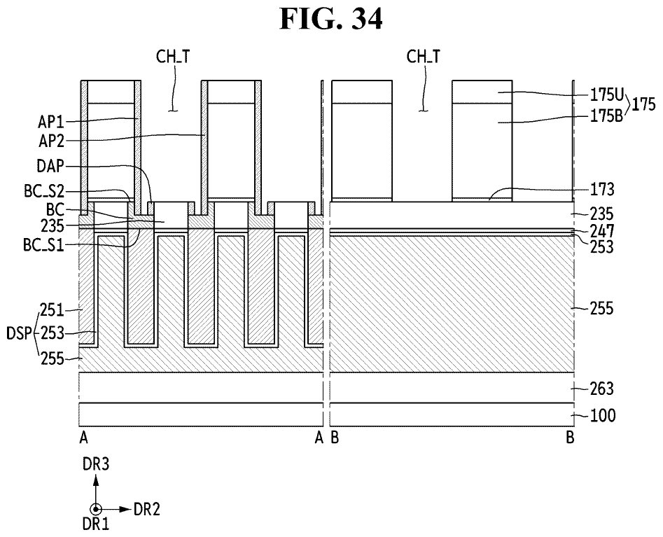

Referring to FIG. 34, the pre-channel film may be formed along the sidewalls and the bottom surfaces of the channel grooves. Through an etching process, the portions of the pre-channel film on the upper surfaces of the protruding insulating patterns 175 may be removed. During the removal of the portions of the pre-channel film on the upper surfaces of the protruding insulating patterns 175, the portions of the pre-channel film formed on the bottom surfaces of the channel grooves may also be removed. As a result, dummy channel patterns DAP may be formed on the sidewalls of the channel grooves.

Subsequent manufacturing processes will hereinafter be explained using the shapes of the first channel patterns AP1 and the second channel patterns AP2 of FIG. 32, but the present disclosure is not limited thereto.

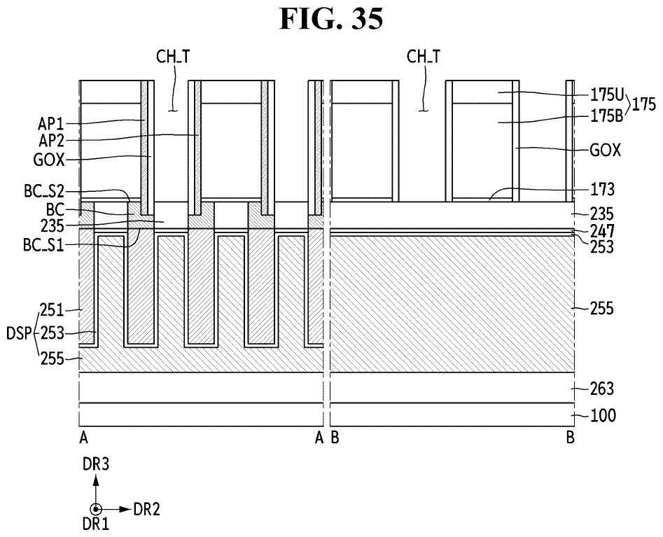

Referring to FIG. 35, a gate insulating film GOX may be formed on the first channel patterns AP1 and the second channel patterns AP2.

The gate insulating film GOX may be formed along the sidewalls and the bottom surfaces of the channel trenches CH_T. The gate insulating film GOX may also be formed along the upper surfaces of the protruding insulating patterns 175.

Thereafter, through an etching process, the portions of the gate insulating film GOX on the bottom surfaces of the channel trenches CH_T and on the upper surfaces of the protruding insulating patterns 175 may be removed.

In some other embodiments, different from what is illustrated, the portions of the gate insulating film GOX on the bottom surfaces of the channel trenches CH_T and on the upper surfaces of the protruding insulating patterns 175 may not be removed.

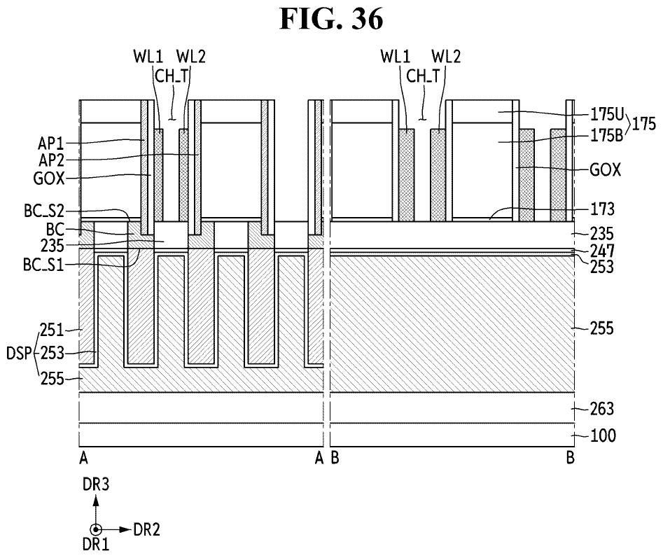

Referring to FIG. 36, first wordlines WL1 and second wordlines WL2 may be formed on the gate insulating film GOX.

The first wordlines WL1 and the second wordlines WL2 may be formed within the channel trenches CH_T.

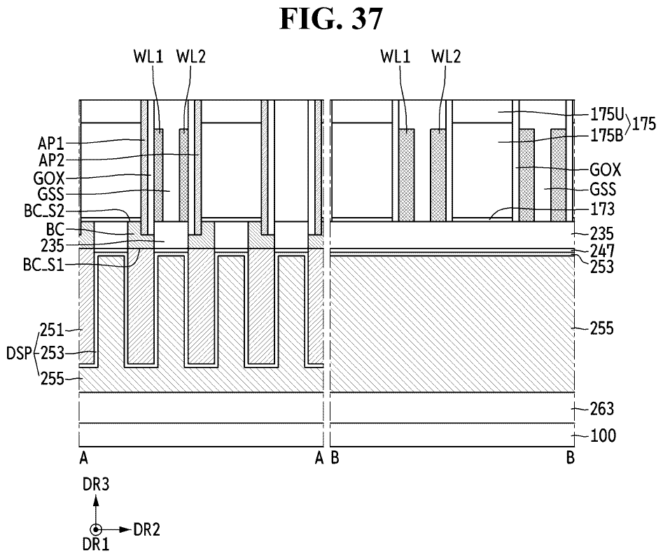

Referring to FIGS. 36 and 37, gate separation patterns GSS may be formed on the first wordlines WL1 and the second wordlines WL2.

The gate separation patterns GSS may be in (e.g., may fill) the channel trenches CH_T.

Thereafter, referring back to FIG. 3, bitlines BL may be formed on the first channel patterns AP1 and the second channel patterns AP2. For example, the channel patterns AP1 and AP2 and the wordlines WL1 and WL2 may be between the bitlines BL and the contact patterns BC.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

Although example embodiments of the present disclosure have been described with reference to the accompanying drawings, the present disclosure is not limited to the above- described embodiments but may be implemented in various different forms. A person skilled in the art will appreciate that the present disclosure may be practiced in other concrete forms without changing the scope or essential characteristics of the present disclosure. Therefore, it should be appreciated that the embodiments as described above are not restrictive but illustrative in all respects.

What is claimed is:

1. A semiconductor memory device comprising:
a contact pattern including a first surface and a second surface that are opposite to each other in a first direction;
a data storage pattern electrically connected to the first surface of the contact pattern;
a channel pattern including a first surface and a second surface that are opposite to each other in the first direction, and a first sidewall and a second sidewall that are opposite to each other in a second direction different from the first direction, wherein the first surface of the channel pattern is electrically connected to the contact pattern, and at least a portion of the first sidewall of the channel pattern is in contact with the contact pattern;
a bitline on the channel pattern, electrically connected to the second surface of the channel pattern, and extending in the second direction; and
a wordline on the second sidewall of the channel pattern and extending in a third direction different from the first and second directions.

2. The semiconductor memory device of claim 1, wherein:
the contact pattern comprises a lower portion that includes the first surface of the contact pattern and an upper portion that includes the second surface of the contact pattern, and
the upper portion of the contact pattern protrudes in the first direction from the lower portion of the contact pattern.

3. The semiconductor memory device of claim 2, wherein a width, in the second direction, of the upper portion of the contact pattern is less than a width, in the second direction, of the lower portion of the contact pattern.

4. The semiconductor memory device of claim 2, wherein:
the first surface of the channel pattern is in contact with the lower portion of the contact pattern, and
the first sidewall of the channel pattern is in contact with the upper portion of the contact pattern.

5. The semiconductor memory device of claim 1, wherein a width, in the second direction, of the first surface of the channel pattern is equal to a width, in the second direction, of the second surface of the channel pattern.

6. The semiconductor memory device of claim 1, wherein a width, in the second direction, of the first surface of the channel pattern is greater than a width, in the second direction, of the second surface of the channel pattern.

7. The semiconductor memory device of claim 1, further comprising:
a dummy channel pattern on the second sidewall of the channel pattern and between the wordline and the contact pattern; and
a gate insulating film extending along the second sidewall of the channel pattern and in contact with the channel pattern and the dummy channel pattern.

8. The semiconductor memory device of claim 7, wherein a height, in the first direction, of the channel pattern is greater than a height, in the first direction, of the dummy channel pattern.

9. The semiconductor memory device of claim 1, further comprising:
a gate insulating film between the wordline and the channel pattern,
wherein the gate insulating film is in contact with the second sidewall of the channel pattern.

10. The semiconductor memory device of claim 1, further comprising:
a protruding insulating pattern on the second surface of the contact pattern and including a channel trench therein,
wherein the channel pattern and the wordline are in the channel trench,
wherein the first sidewall of the channel pattern faces the protruding insulating pattern, and
wherein the wordline is not on the first sidewall of the channel pattern.

11. The semiconductor memory device of claim 1, wherein:
the bitline includes an extension portion extending in the second direction and a protruding portion protruding in the first direction, and
the protruding portion of the bitline protrudes from the extension portion of the bitline toward the channel pattern.

12. A semiconductor memory device comprising:
a contact pattern including a first surface and a second surface that are opposite to each other in a first direction;
a data storage pattern electrically connected to the first surface of the contact pattern;
a channel pattern including a first surface and a second surface that are opposite to each other in the first direction, wherein the first surface of the channel pattern is electrically connected to the contact pattern;
a bitline on the channel pattern, electrically connected to the second surface of the channel pattern, and extending in a second direction different from the first direction;
a wordline between the bitline and the contact pattern, and extending in a third direction different from the first and second directions; and
a gate insulating film between the wordline and the channel pattern,
wherein the contact pattern comprises a lower portion that includes the first surface of the contact pattern and an upper portion that includes the second surface of the contact pattern,
wherein the upper portion of the contact pattern protrudes in the first direction from the lower portion of the contact pattern,
wherein a width, in the second direction, of the upper portion of the contact pattern is less than a width, in the second direction, of the lower portion of the contact pattern, and
wherein the first surface of the channel pattern is in contact with the lower portion of the contact pattern.

13. The semiconductor memory device of claim 12, wherein, in a cross-sectional view, a length of an interface where the channel pattern is in contact with the contact pattern is greater than a width, in the second direction, of the first surface of the channel pattern.

14. The semiconductor memory device of claim 12, wherein:
a width, in the second direction, of the first surface of the channel pattern is equal to a width, in the second direction, of the second surface of the channel pattern, and
the gate insulating film is in contact with the contact pattern.

15. The semiconductor memory device of claim 12, wherein:
a width, in the second direction, of the first surface of the channel pattern is greater than a width, in the second direction, of the second surface of the channel pattern, and
the gate insulating film is not in contact with the contact pattern.

16. The semiconductor memory device of claim 12, further comprising:
a dummy channel pattern in contact with the contact pattern and spaced apart from the channel pattern in the second direction,
wherein the gate insulating film is in contact with the dummy channel pattern.

17. The semiconductor memory device of claim 12, wherein:
the channel pattern includes a first sidewall and a second sidewall that are opposite to each other in the second direction,
the wordline is on the second sidewall of the channel pattern, and
the gate insulating film is in contact with the second sidewall of the channel pattern and is not in contact with the first sidewall of the channel pattern.

18. A semiconductor memory device comprising:
a peripheral gate structure on a substrate;
a contact pattern on the peripheral gate structure, the contact pattern including a first surface and a second surface that are opposite to each other in a first direction;
a data storage pattern electrically connected to the first surface of the contact pattern;
a channel pattern including a first surface and a second surface that are opposite to each other in the first direction, wherein the first surface of the channel pattern is in contact with the contact pattern;
a bitline on the channel pattern, electrically connected to the second surface of the channel pattern, and extending in a second direction different from the first direction; and
a wordline between the bitline and the contact pattern, and extending in a third direction different from the first and second directions,
wherein, in a cross-sectional view, a length of an interface where the channel pattern is in contact with the contact pattern is greater than a width, in the second direction, of the first surface of the channel pattern.

19. The semiconductor memory device of claim 18, wherein the data storage pattern is between the peripheral gate structure and the bitline.

20. The semiconductor memory device of claim 18, wherein the bitline is between the peripheral gate structure and the data storage pattern.
